(19) United States
(12) Patent Application Publication
(10) Pub. No.: US 2023/0215984 A1
(43) Pub. Date: Jul. 6, 2023

(54) NON-SEGMENTED U-SHAPED UBM FOR SHIFTED LUMINANCE

(71) Applicant: Lumileds LLC, San Jose, CA (US)

(72) Inventors: Jeffrey DiMaria, San Jose, CA (US); Toni Lopez, Vaals (NL)

(73) Assignee: Lumileds LLC, San Jose, CA (US)

(21) Appl. No.: 18/120,737

(22) Filed: Mar. 13, 2023

Related U.S. Application Data
(63) Continuation-in-part of application No. 18/055,926, filed on Nov. 16, 2022.
(60) Provisional application No. 63/284,851, filed on Dec. 1, 2021.

(51) Int. Cl. H01L 33/38; H01L 33/20

(52) U.S. Cl. CPC H01L 33/382; H01L 33/20; H01L 27/156

(57) ABSTRACT

Provided is a light-emitting diode (LED) device that includes a continuous non-segmented edge contact along at least one side of a semiconductor layer. A first set of independent contacts connected to a first doped layer and a set of edge contacts connected to the second doped layer. Multiple conductive vias connect the independent contacts to the first doped layer, allowing differing corresponding via currents to be applied to the first doped layer through the vias independent of one another.

### CROSS-REFERENCE TO RELATED APPLICATIONS

This application is a Continuation-In-Part of U.S. application Ser. No. 18/055,926, filed on Nov. 16, 2022, which claims priority to U.S. Provisional Application No. 63/284,851, filed Dec. 1, 2021, the entire disclosures of which are hereby incorporated by reference herein.

### TECHNICAL FIELD

Embodiments of the disclosure generally relate to light emitting diode (LED) devices and methods of manufacturing the same. More particularly, embodiments are directed to apparatus and methods for configuring a spatial distribution of light emission intensity produced by a semiconductor LED.

### BACKGROUND

It is desirable in certain illumination applications (e.g., automotive headlights) to employ semiconductor light-emitting devices (LEDs) that exhibit a specified spatial distribution of emission intensity. For example, low-beam automotive headlights have been observed to exhibit desirable beam intensity profiles when employing LEDs with an intensity distribution having a maximum near one edge of the device and decreasing monotonically toward the opposite edge of the device (referred to herein as a sloped intensity distribution). In another example, high-beam automotive headlights are observed to exhibit desirable bean intensity profiles when employing LEDs with an intensity distribution having a maximum in a central region of the device and decreasing toward the edges of the device (referred to herein as a 2D-peaked intensity distribution). Other intensity distributions can be advantageously employed in other use applications, including automotive and non-automotive applications.

Front-lighting beam distributions can be made by overlapping and stacking of luminance pictures of the light source using tailored optics. Often, however, there is not an optimal mapping possible due to the luminance shape of the source, and efficiency could be improved by use of non-uniform light intensity patterns for one or more LEDs.

Luminance shaping using multiple LEDs to correct for non-uniform lighting of planar panels relies upon a non-uniform pattern density that compensates for a luminous intensity that decreases with increasing distance from the plurality of LEDs in a backlight system. Luminance shaping of a single LED relies upon automotive beam lighting sources that are generally planar but have a radial light intensity drop away from the center. Other controlled luminance distribution schemes are specifically designed for automotive forward lighting and aim to improve overall system performance by concentrating light generation around contact regions of current injection either at the edges of the emitter die or at the edges of etched formed contact vias where no light is generated.

Accordingly, there is a need for non-uniform light intensity patterns for front-lighting beam distributions that use for one or more LEDs.

### SUMMARY

One or more embodiments are directed to a light emitting diode (LED) device. In one or more embodiments, a light emitting diode (LED) device comprises: a first doped semiconductor layer; a second doped semiconductor layer; a plurality of first contacts each electrically connected to the first doped semiconductor layer; a plurality of edge contacts each electrically connected to the second doped semiconductor layer, the plurality of edge contacts comprising a continuous non-segmented layer along at least one side of the second doped semiconductor layer with no separation by an insulating layer; and an array of a plurality of vias arranged across the device, the plurality of vias connecting the plurality of first contacts to the first doped semiconductor layer, each of the plurality of vias connecting at most one corresponding first contact of the plurality of first contacts to the first doped semiconductor layer.

Further embodiments are directed to a light emitting diode (LED) device comprising: a first doped semiconductor layer; a second doped semiconductor layer; a plurality of first contacts each electrically connected to the second doped semiconductor layer; a plurality of edge contacts each electrically connected to the second doped semiconductor layer, the plurality of edge contacts comprising a continuous non-segmented layer along at least one side of the second doped semiconductor layer with no separation by an insulating layer; and an array of a plurality of vias arranged across the device, the plurality of vias connecting the plurality of first contacts to the second semiconductor layer, each of the plurality of vias connecting at most one corresponding first contact of the plurality of first contacts to the second semiconductor layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limited in the figures of the accompanying drawings in which like references indicate similar elements.

FIG. 1 is a schematic side cross-sectional view of a light-emitting diode device according to the prior art;

FIG. 2A, is a schematic side cross-sectional view of light-emitting diode device according to one or more embodiments;

FIG. 2B, is a schematic side cross-sectional view of a light-emitting diode device according to one or more embodiments;

FIG. 2C, is a schematic side cross-sectional view of a light-emitting diode device according to one or more embodiments;

FIG. 2D, is a schematic side cross-sectional view of a light-emitting diode device according to one or more embodiments;

FIG. 3A is a schematic side cross-sectional view of a light-emitting diode device according to one or more embodiments;

FIG. 3B is a schematic side cross-sectional view of a light-emitting diode device according to one or more embodiments;

FIG. 3C is a schematic side cross-sectional view of a light-emitting diode device according to one or more embodiments;

FIG. 3D is a schematic side cross-sectional view of a light-emitting diode device according to one or more embodiments;

FIGS. 4A and 4B are via current magnitude distributions for producing a sloped emission intensity distribution using any of the embodiments of FIGS. 2A-2D or 3A-3D;

FIGS. 5A and 5B are via current magnitude distributions for producing a 1D-peaked emission intensity distributions using any of the embodiments of FIGS. 2A-2D or 3A-3D;

FIGS. 6A and 6B are via current magnitude distributions for producing a 2D-peaked emission intensity distribution using any of the embodiments of FIGS. 2A-2D or 3A-3D;

FIG. 7 is a schematic side cross-sectional view of a light-emitting diode device according to one or more alternative embodiments;

FIG. 8A is a via size distribution for producing a sloped emission intensity distribution using the embodiment of FIG. 7;

FIG. 8B is a via number density distribution for producing a sloped emission intensity distribution using the embodiment of FIG. 7;

FIG. 9 is a schematic cross-sectional view of a n-via contact according to one or more embodiments;

FIGS. 10A to 10D are composite contact die layouts with segmented edge n-contact arrangements for luminance steering according to one or more embodiments;

FIG. 11A is a schematic cross-sectional view of the edge contact in FIG. 10A;

FIG. 11B is a schematic cross-sectional view of a contact in FIG. 10A;

FIGS. 12A to 12F are composite contact die layouts with non-segmented edge n-contact arrangements for luminance steering according to one or more embodiments; and

FIG. 12G is a contact die layout with a non-segmented edge n-contact arrangement on four sides according to the prior art.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

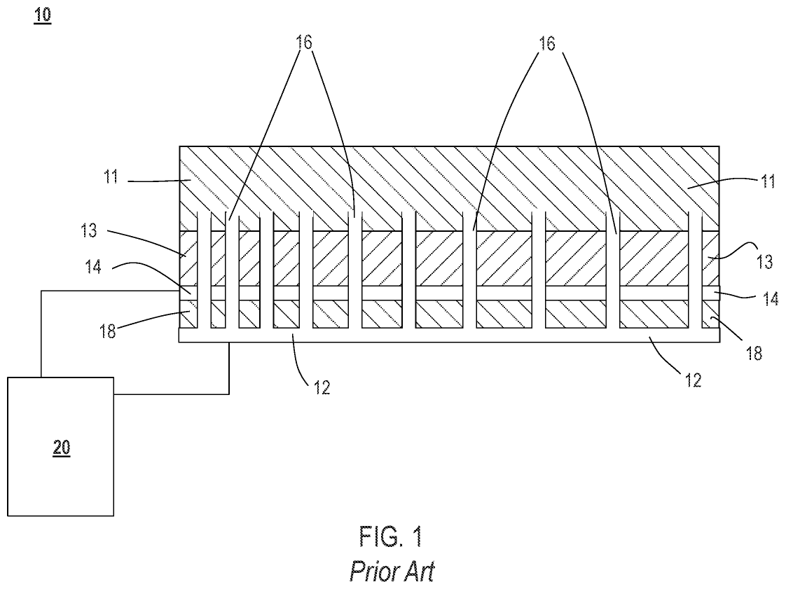

A prior art semiconductor light-emitting device 10 (e.g., as illustrated in FIG. 1) can include a set of conductive vias 16 that connect an n-contact 12 to the n-doped layer 11 of the device 10. The vias 16 are connected directly to one another by all being connected to the conductive n-contact 12. Transverse size and or local number density of the vias 16 can vary with transverse position across the device 10. For a given drive signal level, applied by the drive circuit 20 through the n-contact 12 and thence to all of the vias 16, local carrier recombination density through the device 10 varies as a function of position across the device due to the variation of size or number density of the vias 16. Spatial distribution of local carrier recombination density in turn determines the spatial distribution of emission intensity. A distribution of sizes and positions of the vias 20 can be selected that produces the desired spatial distribution of carrier recombination density.

The arrangement of FIG. 1 has a number of drawbacks. First, structural features formed by spatially selective material processing techniques (e.g., epitaxy or lithography) can become less reproducible or reliable as feature sizes decrease (e.g., as vias get smaller to reduce local carrier recombination density or spacing between them gets smaller to increase local carrier recombination density). For example, that can limit a practicably achievable dynamic range of light emission intensity that can be realized across the device. Second, once fabricated, the spatial distribution of light emission of a given device is fixed. If multiple different emission distributions are desired, multiple corresponding light-emitting devices must be provided, with each one producing only one of the desired emission distributions. That leads to inefficiencies of two types. A device manufacturer must fabricate and inventory multiple different types of light-emitting devices to cover different desirable emission distributions. A device user that requires multiple different emission distributions in a single apparatus (e.g., for both low and high beams in an automotive headlight) must design that apparatus to include multiple light emitting devices, driving up cost and complexity of the apparatus. Therefore, it would be desirable to provide a light-emitting device that can provide multiple different spatial emission distributions.

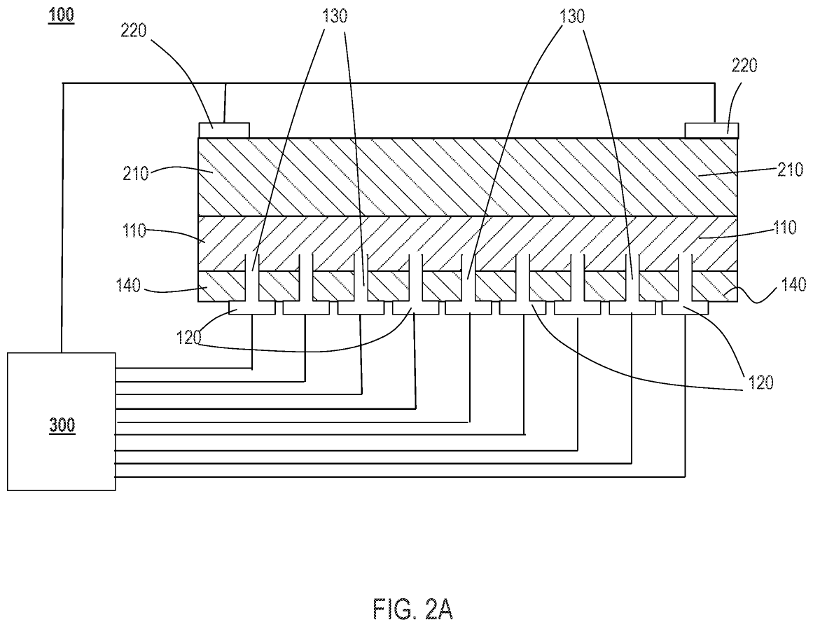

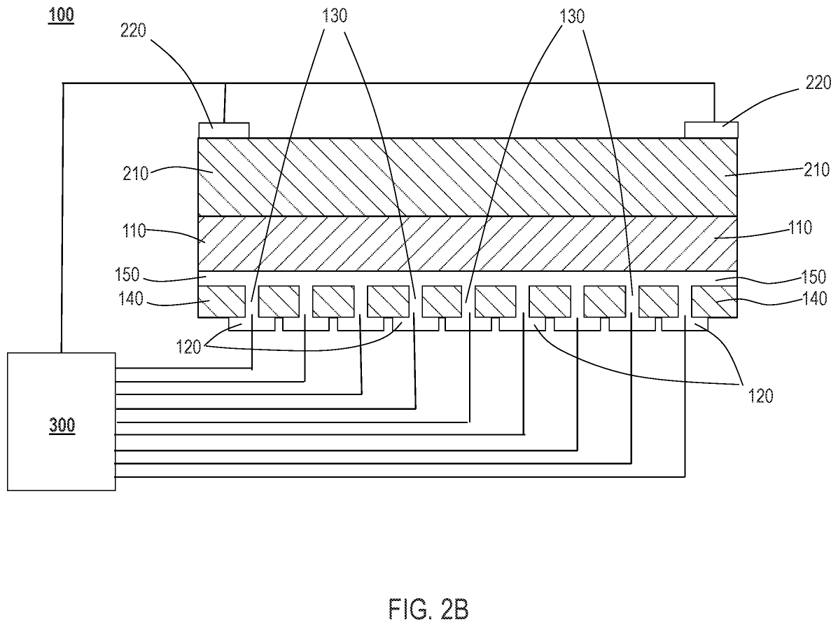

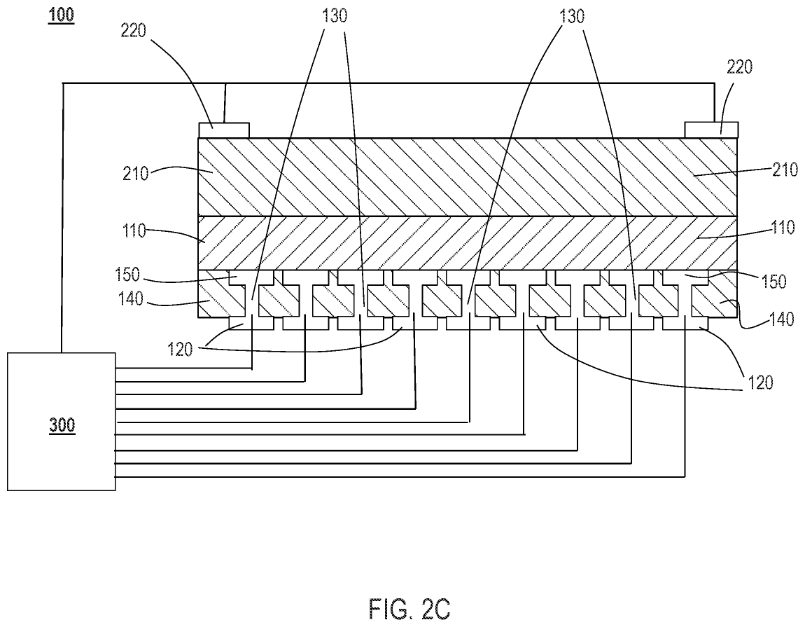

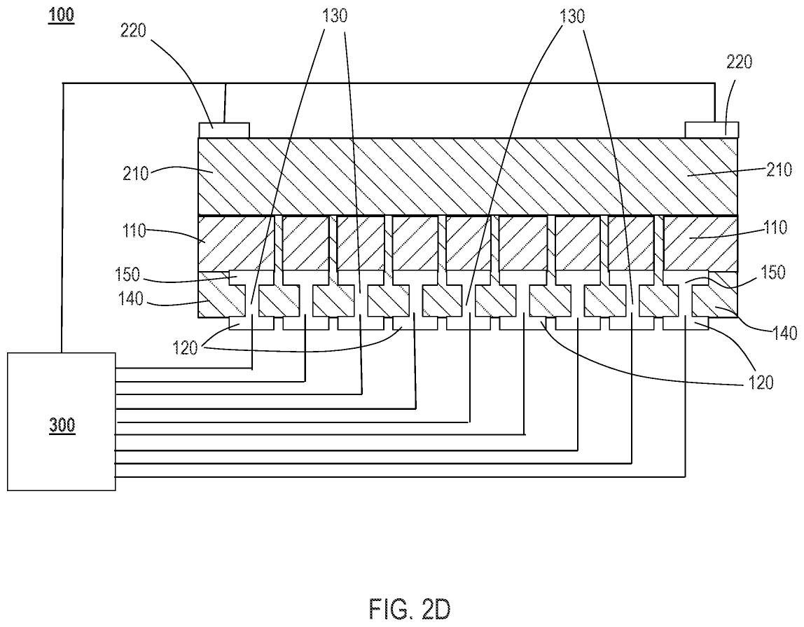

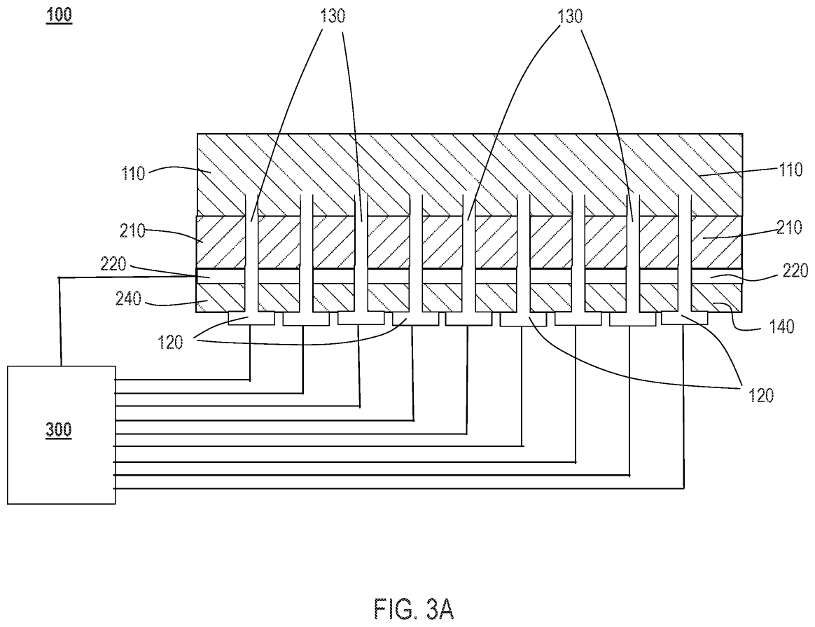

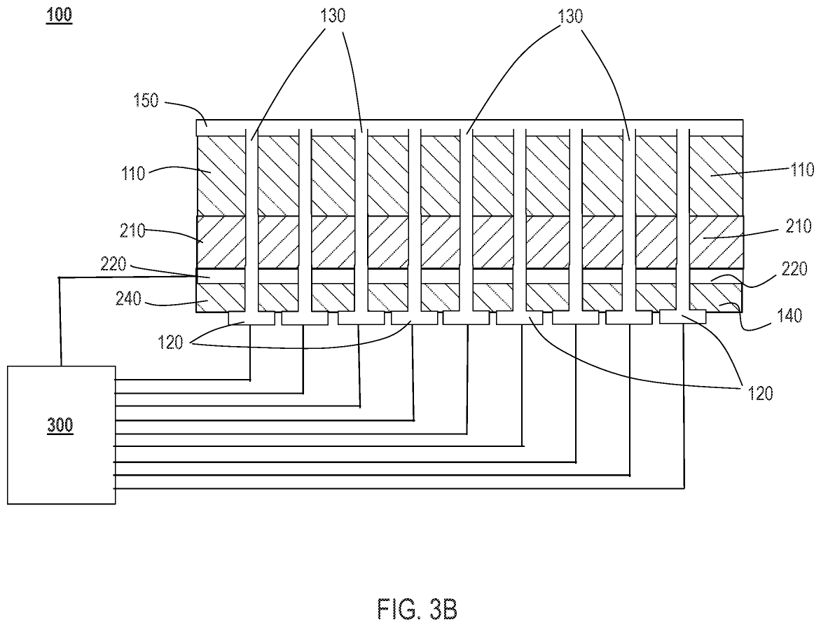

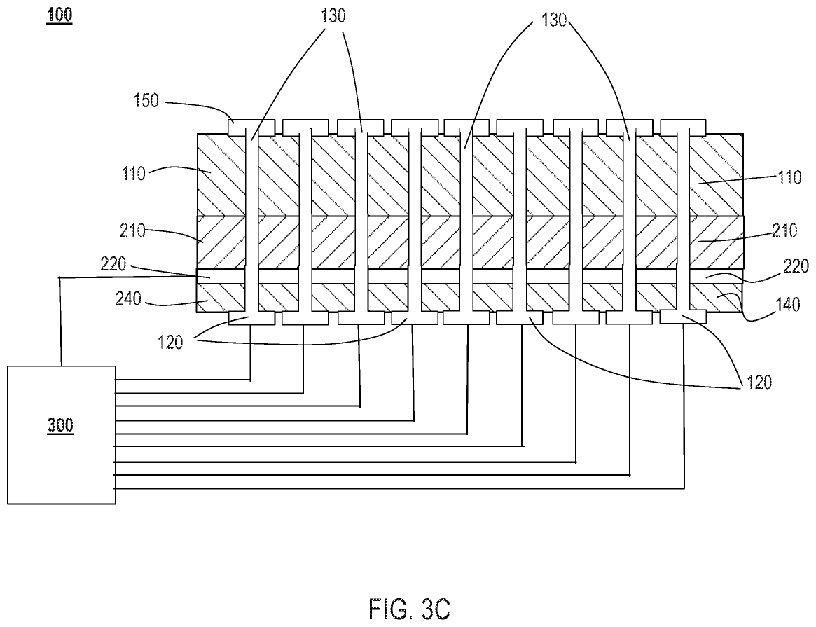

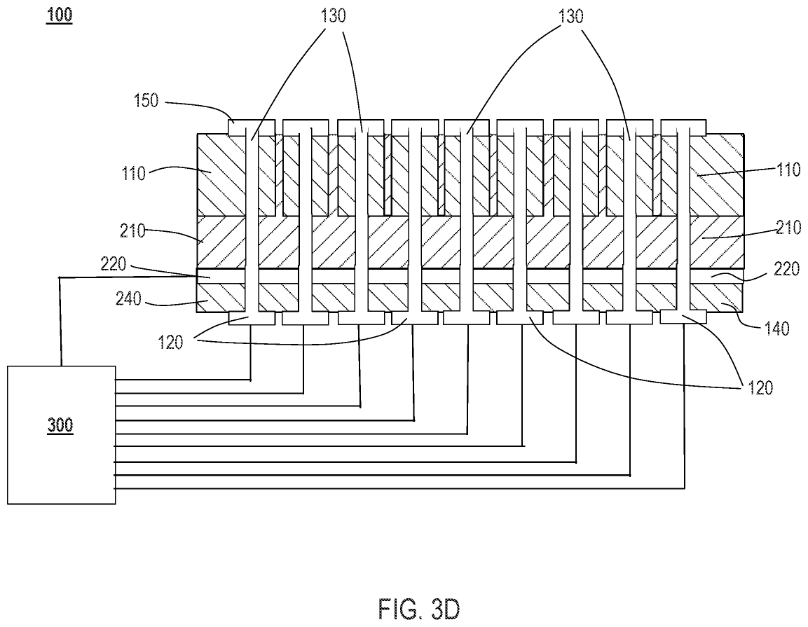

Embodiments of semiconductor light-emitting devices 100 (LEDs) according to one or more embodiments are illustrated schematically in FIGS. 2A-2D and 3A-3D. A semiconductor light emitting device 100 includes first and second doped semiconductor layers 110 and 210, respectively, a first set of electrically conductive contacts 120, a second set of electrically conductive contacts 220, and an array of electrically conductive vias 130.

The first and second doped semiconductor layers 110/210 are arranged for emitting light resulting from carrier recombination at a junction between them. The junction can be of any type or arrangement suitable for generating light in response to current passing through the device 100 under forward-biased conditions. In some embodiments the junction can include one or more active semiconductor layers or one or more quantum wells. Any one or more suitable semiconductor materials can be employed for the first doped semiconductor layer 110, the second doped semiconductor layer 210, and the active layers or quantum well(s) (if present). In one or more embodiments, one or more doped III-V semiconductor materials or alloys thereof can be employed to form the first and second doped semiconductor layers 110/210. In some embodiments that include one or more active layers or quantum wells, those can include one or more doped or undoped III-V semiconductor materials or alloys thereof. The light produced typically is emitted mainly through the doped semiconductor layer 110 or 210 that is farthest from the contacts 120; some emitted light propagates directly from the junction between the doped layers 110/210, while some of the light undergoes one or more reflections within the device 100 before being emitted. The device 100 can include any one or more additional layers, substrates, or structures on its emission side for any one or more suitable purposes (e.g., reduction of reflection; wavelength conversion; collimation, focusing, diffusion, scattering, or other redirection of emitted light; and so forth). The device 100 can be a free-standing structure or can be formed on any suitable solid substrate (typically with the substrate on the side of the device 100 opposite the contacts 120, and therefore typically transparent for the emitted light). In some instances, the device 100 can include conductive bond pads or other similar structures (not shown) connected to the contacts 120 or 220 and arranged for mounting the device 100 to a circuit board or similar structure that provides connections to a drive circuit 300 (described below). Additional conductive or insulating layers that might be employed are omitted from the drawings for clarity.

The first set of contacts 120 includes multiple independent electrically conductive contacts 120 each electrically connected to the first doped semiconductor layer 110. “Independent” contacts are defined herein as being spatially separated from one another so that there is no direct electrical conduction between them; any electrical connections between two independent contacts can only occur indirectly, e.g., by both being connected to the first doped semiconductor layer 110, to an electrode 150 (described below), or to a drive circuit 300 (described below). The second set of contacts 220 includes one or more electrically conductive contacts 220 each electrically connected to the second doped semiconductor layer 210. The array of vias 130 includes multiple electrically conductive vias 130 arranged across the device 100. The vias 130 of the array connect the contacts 120 of the first set to the first doped semiconductor layer 110, with each via 130 connecting at most one corresponding contact 120 of the first set to the first doped semiconductor layer 110. Each via 130 provides a corresponding discrete, localized, circumscribed electrical connection between the first doped semiconductor layer 110 and the corresponding contact 120 of the first set. In one or more embodiments, any suitable electrically conductive material can be employed to form the contacts 120/220 and the vias 130; in embodiments, the contacts 120/220 and the vias 130 can include one or more metals or metal alloys.

In some embodiments, the transverse sizes of the vias 1 30 can vary among the vias 130, or the local number density of the vias 130 can vary with position across the device 100. Such variation can contribute to achieving a desired light emission spatial distribution (described further below). In some embodiments, it may be advantageous for the array of vias 130 to be arranged across the device 100 as a substantially regular grid of substantially identical vias 130. A Tegular grid” is defined herein as an arrangement in which the vias 130 occupy positions of a repeating unit cell; the unit cells of the regular grid can be of any suitable size or shape (e.g., square, rectangular, triangular, hexagonal), and can include any suitable number of vias 130 per unit cell, provided that the size, shape, and number are constant for all unit cells of the regular grid. One simple example would be a rectangular grid with a one via 130 per unit cell at the center of each rectangle; other suitable grid arrangements can be employed. Using a regular grid of substantially identical vias 130, variations arising from fabrication of differing feature sizes are substantially eliminated: each via 130 has the same transverse dimensions, and is the same distance from its nearest neighbors, as all the other vias 130 of the array. Achieving variation of the emitted light intensity across the device, using identical, uniformly spaced vias 130, is described further below, and relies on the independence of the contacts 120. A light emitting device 100 according to one or more embodiments can be of any suitable or desirable transverse dimensions and can include suitable or desirable number of vias 130. Some typical devices can have transverse dimensions from several hundred microns to a few millimeters, and can have arrays of vias that include, e.g., 4×4 n-vias up to 10×10 n-vias or more (more generally, n×m where n and m can differ), or 10×10 so-called e-vias (connecting an electrode layer to a p-contact through an insulating layer) up to 50×50 e-vias or more.

Instead of relying solely upon variation among the vias 130 of size or local their number density or spacing to achieve spatial variation of the emitted light intensity distribution, in the device 100 of one or more embodiments the independent contacts 120 are employed to provide differing corresponding via currents that flow between the first doped semiconductor layer 110 and the contacts 120 through the vias 130. In some embodiments, each contact 120 of the first set is connected to at most one corresponding via 130 of the array. Such an arrangement enables individual control over current flowing through each via 130 independent of the currents flowing through the other vias 130 and provides the highest spatial resolution for controlling local carrier recombination density through the device 100 for a given arrangement of the vias 130. In other embodiments, one or more contacts 120 of the first set can be each connected to multiple corresponding vias 130 of the array. A subset of vias 130 that are attached to the same contact 120 can only be controlled together by altering the total current that flows through the contact 120 and is divided among the vias 130 connected to that contact 120.

FIGS. 2A-2D and 3A-3D illustrate two general example arrangements for a light-emitting device 100 according to one or more embodiments. In the example general arrangement shown in FIGS. 2A-2D, the first doped semiconductor layer 110 is between the first set of contacts 120 and the second doped semiconductor layer 210, and an electrically insulating layer 140 is between the first doped semiconductor layer 110 and the first set of contacts 120. The vias 130 connect contacts 120 of the first set to the first doped semiconductor layer 110 through the insulating layer 140. In some embodiments that are thus arranged, the first doped semiconductor layer 110 can be a p-doped layer and the second doped semiconductor layer 210 can be an n-doped layer. The insulating layer 140 can include any one or more suitable materials; in some embodiments the insulating layer 140 includes doped or undoped silica. In some embodiments arranged as in FIGS. 2A-2D, the contacts 120 can be metal contacts, and the contacts 120 and the insulating layer 140 can be arranged so as to act as a composite optical reflector for light emitted by the device 100. The metallic contacts 120 often can be lossy as reflectors; the presence of the insulating layer 140 reflects at least some of the light propagating within the layers 110/210 before reaching the contacts 120, thereby reducing optical loss. In some embodiments (e.g., as in FIG. 2A), the vias 130 are connected directly to the first doped semiconductor layer 110. In some embodiments (e.g., as in FIGS. 2B-2D), an electrode layer 150 is between the first doped semiconductor layer 110 and the insulating layer 140 and is in direct contact with the first doped semiconductor layer 110. The electrode layer 150 is substantially transparent for light emitted by the device 100, and the vias 130 (arranged as e-vias in these embodiments) connect the first doped semiconductor layer 110 to the contacts 120 by connecting the electrode layer 150 to the contacts 120. The electrode layer 150 can include any one or more suitable materials; in some embodiments indium tin oxide (ITO) or indium zinc oxide (IZO) can be employed. In some embodiments (e.g., as in FIG. 1B), the electrode 150 can be a single contiguous layer spanning most or nearly all of the device 100 (except for, e.g., other vias that pass through it, if present).

In other embodiments (e.g., as in FIGS. 2C and 2D), it can be desirable to arrange the electrode layer 150 as multiple discrete areal segments separated by electrically insulating material, thereby substantially preventing transverse electrical conduction between adjacent areal segments of the electrode layer 150. In some embodiments that include such an arrangement, each areal segment of the electrode layer 150 can be connected to at most one corresponding contact 120 by one or more corresponding vias 130; in other embodiments that include such an arrangement, each areal segment of the electrode layer 150 can be connected to multiple different contacts 120 by corresponding vias 130. The segmentation of the electrode layer 150 can enhance the spatial resolution of the carrier recombination spatial distribution provided by the vias 130, by somewhat limiting the transverse movement of charge carriers to or from any given via 130 to the area occupied by the corresponding areal segment of the electrode layer 150. In the embodiments of FIGS. 2A-2C, the first doped semiconductor 110 can be a single contiguous layer spanning most or nearly all of the device 100. Further enhancement of spatial resolution can be achieved in some embodiments (e.g., as in FIG. 2D), by division of the first doped semiconductor layer 110 into multiple discrete areal segments separated by electrically insulating material. In such an arrangement movement of charge carriers between a given contact 120 and the junction is confined transversely by insulating material separating the corresponding areal segments of the electrode layer 150 and the first doped semiconductor layer 110 from adjacent segments. If suitable or desirable, in some embodiments the second doped semiconductor layer 210 can be similarly divided into discrete areal segments (not shown).

In the example general arrangement shown in FIGS. 3A-3D, the second doped semiconductor layer 210 is between the first set of contacts 120 and the first doped semiconductor layer 110, and an electrically insulating layer 240 separates the second doped semiconductor layer 210 from the first set of contacts 120. A metal layer between the insulating layer 240 and second doped semiconductor layer 210 acts as the one or more contacts 220 and can also act as an optical reflector for light emitted by the device 100. The vias 130 connect contacts 120 to the first doped semiconductor layer 110 through the insulating layer 240, the contact 220, and the second doped semiconductor layer 210, and the vias 130 are electrically insulated from the one or more contacts 220 and from the second doped semiconductor layer 210. In some embodiments that are thus arranged, the first doped semiconductor layer 110 can be an n-doped layer and the second doped semiconductor layer 210 can be a p-doped layer. The insulating layer 240 can include any one or more suitable materials; in some embodiments the insulating layer 240 includes doped or undoped silica. In some embodiments (e.g., as in FIG. 3A), the vias 130 are connected directly to the first doped semiconductor layer 110 (i.e., arranged as n-vias if the layer 110 is an n-doped layer). In some embodiments, (e.g., as in FIGS. 3B-3D), an electrode layer 150 is formed on and in direct contact with the first doped semiconductor layer 110. The electrode 150 is substantially transparent for light emitted by the device 100, and the vias 130 connect the first doped semiconductor layer 110 to the contacts 120 by connecting the electrode 150 to the contacts 120. The electrode layer 150 can include any one or more suitable materials; in some embodiments indium tin oxide (ITO) or indium zinc oxide (IZO) can be employed. In some embodiments (e.g., as in FIG. 3B), the electrode 150 can be a single contiguous layer spanning most or nearly all of the device 100.

In other embodiments (e.g., as in FIGS. 3C and 3D), it can be desirable to arrange the electrode layer 150 as multiple discrete areal segments separated by electrically insulating material or empty space, thereby substantially preventing transverse electrical conduction between adjacent areal segments of the electrode layer 150. In some embodiments that include such an arrangement, each areal segment of the electrode layer 150 can be connected to at most one corresponding contact 120 by one or more corresponding vias 130; in other embodiments that include such an arrangement, each areal segment of the electrode layer 150 can be connected to multiple different contacts 120 by corresponding vias 130. As noted above, the segmentation of the electrode layer 150 can enhance the spatial resolution of the carrier recombination spatial distribution provided by the vias 130, by somewhat limiting the transverse movement of charge carriers to or from any given via 130 to the area occupied by the corresponding areal segment of the electrode layer 150. In the embodiments of FIGS. 3A-3C, the first doped semiconductor 110 can be a single contiguous layer spanning most or nearly all of the device 100 (except for, e.g., other vias that pass through it, if present). Further enhancement of spatial resolution can be achieved in some embodiments (e.g., as in FIG. 2D), by division of the first doped semiconductor layer 110 into multiple discrete areal segments separated by electrically insulating material. As noted above, in such an arrangement movement of charge carriers between a given contact 120 and the junction is confined transversely by insulating material separating the corresponding areal segments of the electrode layer 150 and the first doped semiconductor layer 110 from adjacent segments. If suitable or desirable, in some embodiments the second doped semiconductor layer 210 can be similarly divided into discrete areal segments (not shown).

In some instances, the arrangements of FIGS. 2A-2D may be advantageous relative to the arrangement of FIGS. 3A-3D, for a number of reasons. Because the arrangements of FIGS. 3A-3D require vias 130 that pass through the junction between the doped semiconductor layers 110/210 and preclude carrier recombination and light emission from the areas occupied by the vias 130, those arrangements necessarily include dark spots in the emission intensity distribution corresponding to the locations of the vias 130. Because vias 130 are not required to cross the junction in the arrangements of FIGS. 2A-2D, such dark spots can be reduced or eliminated. In addition, vias 130 formed in the arrangements of FIGS. 3A-3D must pass entirely through one of the doped semiconductor layers, through the junction (and any active layers or quantum wells present there), and into the other doped semiconductor layer. Those vias 130 also must be electrically insulated from those layers. In contrast, the vias 130 in the arrangements of FIGS. 2A-2D typically pass through fewer layers (in some instances through only a single layer of insulating material) and do not pass through the junction. As a result, the fabrication process for forming the vias 130 for the arrangement of FIGS. 3A-3D is necessarily more complex and includes additional deposition, mask, and etch steps, compared to a fabrication process for forming the vias 130 for the arrangements of FIGS. 2A-2D. In particular, formation of vias 130 that pass through one or more active layers or quantum wells at the junction between the doped semiconductor layers 110/210 can be particularly problematic.

In addition to the vias 130 connected to the contacts 120, in some embodiments the first set of contacts 120 can include one or more edge contacts positioned about the periphery of the device 100 (not shown). In some embodiments, the second set of contacts 220 can include one or more edge contacts positioned about the periphery of the device 100 (e.g., as in FIGS. 3A-3D), or can include one or more areal contacts 220 on the same side of the device 100 as the contacts 120 (not shown) or on the opposite side of the device 100 (e.g., as in FIGS. 2A-2D). The arrangements shown in FIGS. 2A-2D, and 3A-3D are chosen as a matter of convenience only, because they result in less cluttered drawings; similarly, additional conductive or insulating layers that might be employed for establishing connections among the doped semiconductor layers 110/210, the contacts 120/220, or the drive circuit 300 are omitted from the drawings for clarity. In some embodiments, the device 100 can include a second array of multiple electrically conductive vias (not shown) arranged across the device 100. In such embodiments the vias of that second array can connect contacts 220 to the second doped semiconductor layer 210, and each such via provides a corresponding discrete, localized, circumscribed electrical connection between the second doped semiconductor layer 210 and a corresponding contact 220. In some embodiments that include a second array of vias, the second set of contacts 220 can include multiple independent electrically conductive contacts 220, and each via of the second array can connect at most one corresponding contact 220 of the second set to the second doped semiconductor layer; in other words, in those embodiments the contacts 220 and the vias of the second array can be arranged as described above for the contacts 120 and the vias 130 of the first array.

The various arrangements described above for the multiple independent contacts 120 and the multiple vias 130 can be employed to conduct differing corresponding via currents through each of the vias 130, resulting in position dependent carrier recombination density and corresponding position dependent light emission intensity produced by the device 100. To achieve that result, a light emitting device 100 according to one or more embodiments can include a drive circuit 300 connected to the first and second sets of contacts 120/220. The drive circuit can be arranged in any suitable way and can include any suitable set of components or circuit elements, including but not limited to analog components, digital components, active components, passive components, ASICs, computer components (e.g., processors, memory, or storage media), analog-to-digital or digital-to-analog converters, and so forth. The drive circuit 300 provides electrical drive current that flows through the device 100 and causes the device 100 to emit light.

The drive circuit 300 is further structured and connected so that (i) corresponding portions of the electrical drive current flow through one or more of the vias 130 as corresponding via currents, and (ii) each via current magnitude differs from the corresponding via current magnitude of at least one other of the vias 130. In other words, the via current magnitudes can differ among the different via 130, and the spatial distribution of those via current magnitudes determines the local carrier recombination density, which in turn determines the local light emission intensity.

In some embodiments the contacts 120 and the vias 130 can be connected one-to-one, enabling individual control over the via current magnitude flowing through each via 130, independent of via current magnitudes flowing through the other vias 130 of the array. Such fine-grained control may not be necessary in every instance, so in some embodiments some or all of the contacts 120 can each be connected to multiple corresponding vias 130, and some or all of the vias 130 can be connected to a corresponding contact 120 along with one or more other vias 130. In such an arrangement, current flowing through a contact 120 would be substantially equally divided among the vias 130 connected to it (assuming substantially identical vias 130), so that substantially equal via current magnitudes flow through each of those multiple vias 130 that are connected to the same contact 120. In one specific such example, the vias 130 can be arranged in multiple rows that each includes multiple vias 130. A Tow” is defined as a subset of the vias 1 30 that are all at the same distance, or within a relative narrow range of distances, from one edge of the device 100. Embodiments of such rows can include, e.g., multiple vias 130 arranged along a single straight line or along a zigzagging line (e.g., as might arise if the row included multiple vertices of a row of hexagonal unit cells). Whatever its detailed arrangement, each row extends across the device 100 along a first transverse dimension and the multiple rows can be arranged across the device 100 along a second, orthogonal transverse dimension. Each via 130 of a given row can be connected to a single corresponding contact 120 that is different from corresponding contacts 120 connected to one or more other row of vias 130. Each row current is the sum of the via current magnitudes flowing through the corresponding vias 130 of that row. In some embodiments the rows and contacts 120 can be connected one-to-one; in other embodiments one or more of the contacts 120 can be connected to a group of multiple rows. In some embodiments the vias 130 can be organized into rows not by connecting contacts 120 to multiple vias 130 directly, but instead by configuring the drive circuit 300 to deliver the same via drive current magnitude to all of the vias 130 that make up a given row through their corresponding independent contacts 120.

Such a grouping of the vias 130 into rows, whether by direct connection to common contacts 120 or by operation of the drive circuit 300 to couple certain groups of independent vias 130, can be well-suited for producing a so-called sloped light emission intensity distribution that has a maximum at or relatively near a first edge of the device and decreases monotonically toward the opposite edge of the device 100 (discussed further below). To achieve such an emission intensity distribution, the drive circuit can provide a corresponding row current to each row that decreases monotonically across the device 100 along the second transverse dimension (i.e., perpendicular to the rows).

There are several ways in which differing via current magnitudes can be applied among the multiple vias 130. In one or more embodiments the via current magnitude will have minimum and maximum values that can be delivered by the drive circuit 300; in many of those embodiments the minimum via current magnitude can be about equal to zero. In some embodiments, each via 130 (or group of vias 130 connected to the same contact 120) can be either “off” (carrying the minimum via current magnitude) or “on” (carrying the maximum via current magnitude). In some other embodiments, each via 130 or group of connected vias 130 can also carry via current magnitudes that are between the minimum and maximum (e.g., a percentage or fraction of the maximum via current magnitude), in discrete steps in some embodiments or over a continuous range in other embodiments. The drive circuit 300 can be arranged in some embodiments to deliver those intermediate via current levels as DC currents to the respective vias 130; in other embodiments the drive circuit 300 can be arranged to apply the specified minimum and maximum via current magnitudes alternating at a frequency above the subjective flicker fusion threshold (e.g., above about 60 Hz, above about 90 Hz, above about 120 Hz, or above about 200 Hz) and with a corresponding duty cycle between zero and one that can be selected for each via 130 (or group of connected vias 130) to achieve the desired time-averaged via current magnitude.

The drive circuit can be arranged to provide one or more specified spatial distributions across the device 100 of the differing via current magnitudes provided to the corresponding vias 130 of the array. Each specified via current magnitude distribution among the vias 130 results in corresponding spatial distribution of carrier recombination and light emission intensity across the device 100. For a desired light emission intensity spatial distribution, a corresponding distribution of via current magnitudes can be specified that results, in combination with the spatial arrangement of the vias 130, in an acceptable approximation of the desired emission distribution. Whether a given approximation is “acceptable” can depend on the particular use of the light-emitting device 100; some uses can have more stringent requirements than others. Various emission distributions can be advantageously employed in automotive applications (e.g., for headlight low or high beams), or in other, non-automotive applications. A method for using a light-emitting device 100 according to one or more embodiments comprises operating the drive circuit 300 to provide a specified spatial distribution of via current magnitudes to the vias 130 and thereby cause the device 100 to emit light according to a corresponding emission intensity distribution.

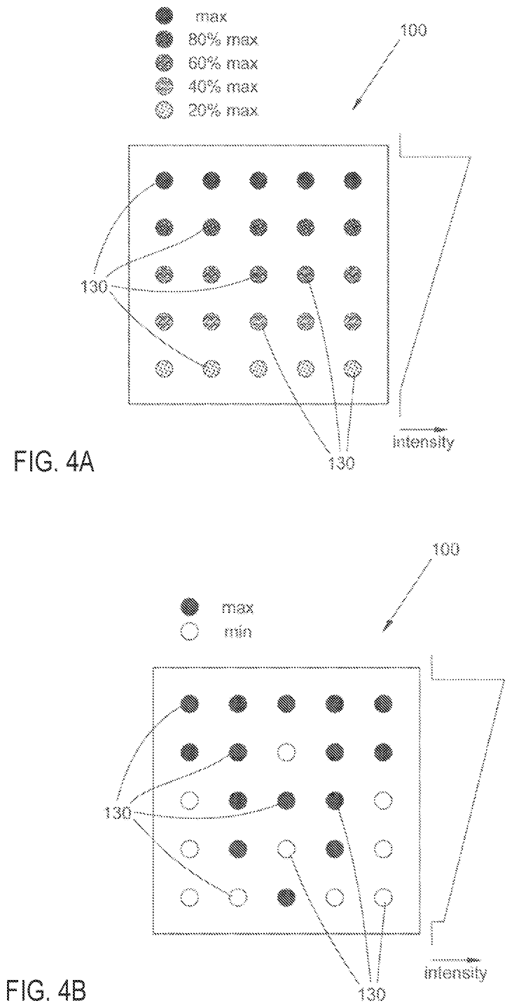

One example of a desired light emission intensity distribution is the sloped distribution mentioned above, wherein the emission intensity is maximum along or near a first edge of the device and decreases in one dimension toward the opposite edge of the device. Such an emission intensity distribution can be advantageously employed in, e.g., low-beam automotive headlights. A sloped emission intensity distribution can be approximated by configuring the drive circuit 300 to provide via current magnitudes distributed among the vias 130 that result in the desired carrier recombination distribution, which can be achieved in a number of ways using a regular array of identical vias 130. In some embodiments the via current magnitude for each via 130 can monotonically decrease with increasing distance from the first edge, either continuously or in steps, using either variable DC currents or variable duty cycle between fixed minimum and maximum via current magnitudes. In one specific example, for a device 100 with a 5×5 array of vias 130, the maximum via current magnitude is applied to each via 130 of the first row, 80% of the maximum is applied to the second row, 60% of the maximum is applied to the third row, 40% of the maximum is applied to the fourth row, and 20% of the maximum is applied to the fifth row (illustrated schematically in FIG. 4A; other array sizes and other position dependencies can be employed). In some embodiments each via 130 receives either the minimum or maximum via current magnitude but no intermediate value, and the number of vias 130 receiving the maximum via current magnitude decreases by row across the device 100. In another specific 5×5 example, the maximum via current magnitude is applied to five vias of the first row, four vias of the second row, three vias of the third row, two vias of the fourth row, and one via of the fifth row, while all other vias 130 receive the minimum via current magnitude (illustrated schematically in FIG. 4B; other array sizes and other position dependencies can be employed). Note that between the first edge of the device 100 and those vias 130 closest to that first edge, the light emission intensity typically would increase from the zero just beyond the edge to a maximum intensity near the first row of vias of the device 100. That initial increase typically has no practical effect, and devices exhibiting the initial increase can nevertheless be considered to have a monotonically decreasing light emission intensity profile.

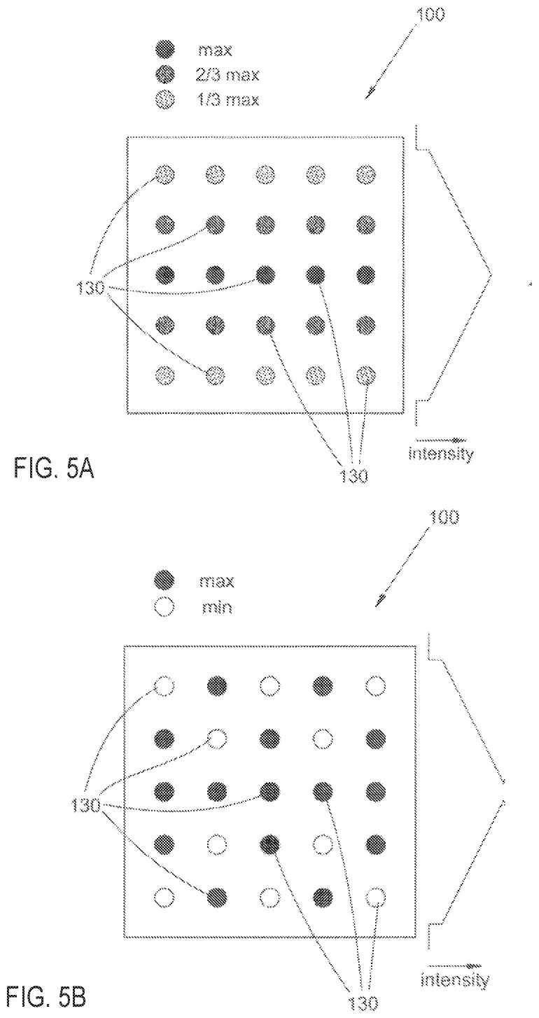

Another example of a desired light emission intensity distribution is a so-called 1D-peaked distribution, wherein the emission intensity has a maximum along a line across a central region of the device 100 and decreases in both directions along one transverse dimension toward opposite edges of the device 100. A 1D-peaked emission intensity distribution can be approximated by configuring the drive circuit 300 to provide via current magnitudes distributed among the vias 130 that result in the desired carrier recombination distribution, which can be achieved in a number of ways using a regular array of identical vias 130. In some embodiments the via current magnitude for each via 130 can decrease from the center toward the opposite edges, either continuously or in steps, using either variable DC currents or variable duty cycle between fixed minimum and maximum via current magnitudes. In a specific 5×5 example, the maximum via current magnitude is applied to each via 130 of the third row, ⅔ of the maximum is applied to the second and fourth rows, and ⅓ of the maximum is applied to the first and fifth rows (illustrated schematically in FIG. 5A; other array sizes and other position dependencies can be employed). In some embodiments each via 130 receives either the minimum or maximum via current magnitude but no intermediate value, and the number of vias 130 receiving the maximum via current magnitude decreases by row across the device 100 from the central row. In a specific 5×5 example, the maximum via current magnitude is applied to five vias of the third row, three vias of the second and fourth rows, and two vias of the first and fifth rows, while all other vias 130 receive the minimum via current magnitude (illustrated schematically in FIG. 5B; other array sizes and other position dependencies can be employed).

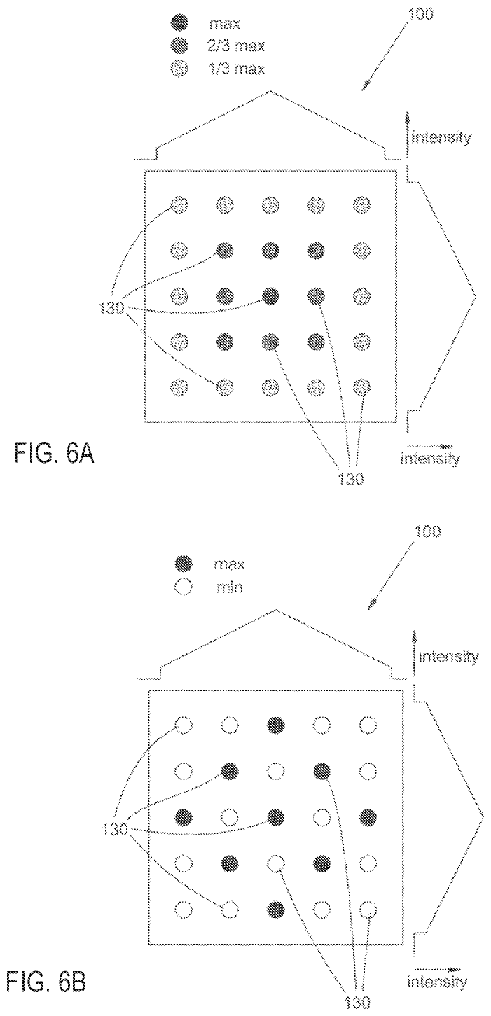

Another example of a desired light emission intensity distribution is a so-called 2D-peaked distribution, wherein the emission intensity has a maximum in a central region of the device 100 and decreases in both directions along both transverse dimensions toward the edges of the device 100. Such an emission intensity distribution can be advantageously employed in, e.g., high-beam automotive headlights. A 2D-peaked slope emission intensity distribution can be approximated by configuring the drive circuit 300 to provide via current magnitudes distributed among the vias 130 that result in the desired carrier recombination distribution, which can be achieved in a number of ways using a regular array of identical vias 130. In some embodiments the via current magnitude for each via 130 can decrease from the center toward all edges, either continuously or in steps, using either variable DC currents or variable duty cycle between fixed minimum and maximum via current magnitudes. In a specific 5×5 example, the maximum via current magnitude is applied to the center via 130 of the third row, ⅔ of the maximum is applied to the second through fourth vias 130 of the second and fourth rows and to the second and fourth vias 103 of the third row, and ⅓ of the maximum is applied to the first and fifth rows and the first and fifth vias of the second through fourth rows (illustrated schematically in FIG. 6A; other array sizes and other position dependencies can be employed). In some embodiments each via 130 receives either the minimum or maximum via current magnitude but no intermediate value, and the number of vias 130 receiving the maximum via current magnitude decreases distance across the device 100 from the central via 130. In a specific 5×5 example, the maximum via current magnitude is applied to the center via 130 of the third row, the second and fourth vias 130 of the second and fourth rows, the first and fifth vias 1 30 of the third row, and the third via 1 30 of the first and fifth rows, while all other vias 130 receive the minimum via current magnitude (illustrated schematically in FIG. 5B; other array sizes and other position dependencies can be employed).

It should be noted that all of the different via current distributions described and shown herein, and myriad others, can all be achieved using a single light-emitting device 100, or by a set of identically arranged light-emitting devices 100. Those different via current distributions, and the corresponding different emission distributions, result from corresponding different modes of operation of the drive circuit 300, illustrating the utility of the various arrangements of the light emitting device 100 according to one or more embodiments, as further elaborated below.

In some embodiments the drive circuit 300 provides only a single specified spatial distribution across the device 100 of the corresponding magnitudes of the via currents, so that the device is arranged so as to provide only a single corresponding spatial distribution of light emission intensity. Although each device 100 produces only a single emission intensity distribution, a manufacturer can provide a variety of different light emitting apparatus that produce a variety of corresponding different emission intensity distributions, and yet all incorporate the same light-emitting device 100. The differences in the emission intensity distributions arise from difference between configuration of the drive circuit 300 and its connections among the multiple contacts 120. For example, the six different embodiments described above could all be made using the same device 100 with a 5×5 array of identical vias 130, because the independence of the contacts 120 enables each the via current magnitude to be applied through a corresponding contact 120 independent of other via currents applied through other contacts 120. The differences among the respective emission intensity distributions of the preceding embodiments can all be implemented by differences in configuration or operation of their respective drive circuits 300.

In other embodiments, the drive circuit 300 can be arranged so as to enable dynamic switching among two or more different specified spatial distributions of via current magnitudes provided by the drive circuit 300. That dynamic switching in turn enables dynamic alteration the spatial distribution of light emission intensity across the device 100, which can be advantageously employed in a variety of ways. Again, referring to the 5×5 device embodiments above, a drive circuit 300 can be configured to enable switching among any two or all three of those emission intensity distributions, simply by suitably rerouting or altering via currents among the vias 130 of the device 100. In automotive headlights, for example, instead of having two separate sets of conventional devices 10 (one sloped and one 2D-peaked) and switching between them for low and high beams, a single set of devices 100 can be employed and the drive circuit 300 used to alter the emission distribution between the sloped distribution (for low beams) and the 2D-peaked distribution (for high beams). Such dynamic control of the emission intensity distribution could also be employed, e.g., for lateral or vertical headlight beam steering as a car makes a turn or crests a hill, or for any number of other automotive and non-automotive purposes. A method of one or more embodiments comprises: (A) selecting a first specified spatial distribution of via current magnitudes; (B) operating the drive circuit 300 to provide the first specified spatial distribution of via current magnitudes to the vias 130 and thereby cause the device 100 to emit light according to a corresponding first emission intensity distribution; (C) selecting a second specified spatial distribution of via current magnitudes that differs from the first specified spatial distribution of via current magnitudes; and (D) operating the drive circuit 300 to provide the second specified spatial distribution of via current magnitudes to the vias 130 and thereby cause the device 100 to emit light according to a corresponding second emission intensity distribution that differs from the first emission intensity distribution.

A method for making a light-emitting device 100 according to one or more embodiments comprises: (A) using any one or more suitable spatially selective material processing techniques, forming the first and second doped semiconductor layers 110/210 with the junction between them; (B) using any one or more suitable spatially selective material processing techniques, forming the array of vias 130 connected to the first doped semiconductor layer 110; (C) using any one or more suitable spatially selective material processing techniques, forming the first set of contacts 120 connected to the first doped semiconductor layer 110 by the array of vias 130; and (D) using any one or more suitable spatially selective material processing techniques, forming the second set of contacts 220 connected to the second doped semiconductor layer 210. Another method for making a light-emitting device comprising connecting the drive circuit 300 to the first and second sets of contacts 120/220 of the light-emitting device 100 and arranging the drive circuit 300 to provide a specified spatial distribution of via current magnitudes to the vias 130.

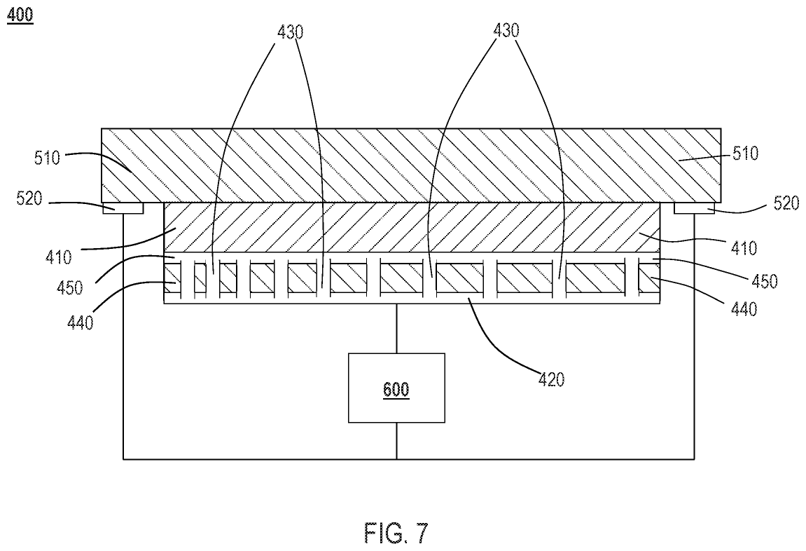

Another light-emitting device 400 according to one or more embodiments is illustrated schematically in FIG. 7 and includes p-doped and n-doped semiconductor layers 410 and 510, respectively, a first set of electrically conductive contacts 420, a second set of electrically conductive contacts 520, and an array of electrically conductive vias 430. The p-doped and n-doped semiconductor layers 410/510 are arranged for emitting light resulting from carrier recombination at a junction between them. The junction can be of any type or arrangement suitable for generating light in response to current passing through the device 400 under forward-biased conditions. In some embodiments the junction can include one or more active semiconductor layers or one or more quantum wells. Any one or more suitable semiconductor materials can be employed for the p-doped semiconductor layer 410, the n-doped semiconductor layer 510, and the active layers or quantum well(s) (if present). In many embodiments one or more doped III-V semiconductor materials or alloys thereof are employed to form the p- and n-doped semiconductor layers 410/520. In many embodiments that include one or more active layers or quantum wells, those can include one or more doped or undoped III-V semiconductor materials or alloys thereof.

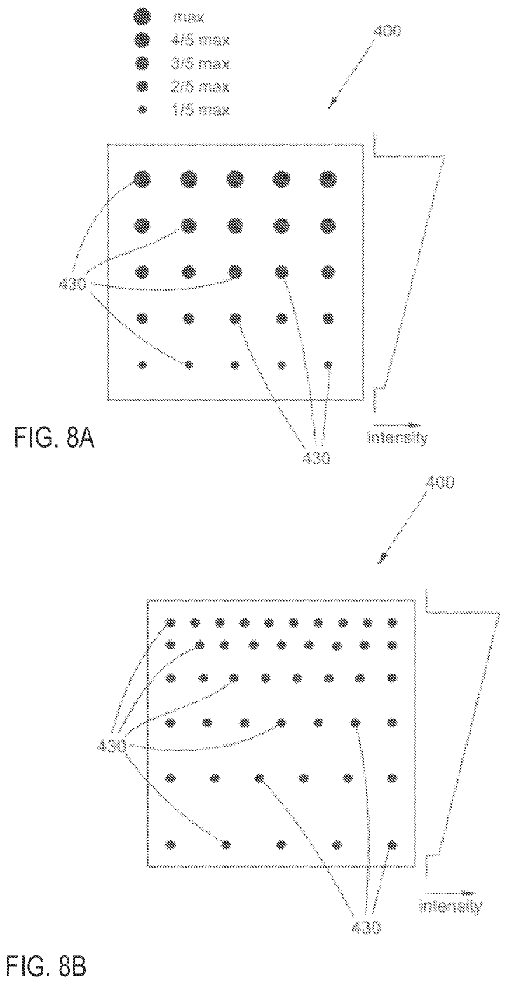

The first set of contacts 420 includes one or more electrically conductive contacts 420 each electrically connected to the p-doped semiconductor layer 410; if multiple contacts 420 are present they are directly coupled or operated as if they were, and so shall be referred to in the singular. The second set of contacts 520 includes one or more electrically conductive contacts 520 each electrically connected to the n-doped semiconductor layer 510; if multiple contacts 520 are present they are directly coupled or operated as if they were, and so shall be referred to in the singular. The array of vias 430 includes multiple electrically conductive vias 430 arranged across the device 400. The vias 430 of the array connect the contact 420 to the p-doped semiconductor layer 410, with each via 430 providing a corresponding discrete, localized, circumscribed electrical connection between the p-doped semiconductor layer 410 and the contact 420. The contacts 420/520 and the vias 430 can include any one or more suitable electrically conductive materials; metals typically can be employed. The array of vias 430 is arranged across the device 400 so that one or both of via local number density (equivalently, via spacing) or via transverse area varies according to position across the device 400 (e.g., variation of via transverse area in FIG. 8A, and variation of via local number density in FIG. 8B). That variation in turn results in a corresponding spatial distribution of light emission intensity that varies across the device 400 according to the arrangement of the array of vias 430. The device 400 can further include an electrically insulating layer 440 between the p-doped semiconductor layer 410 and the contact 420, wherein the vias 430 connect the contact 420 to the p-doped semiconductor layer 410 through the insulating layer 440. The insulating layer 440 can include any one or more suitable materials; doped or undoped silica is often employed.

Any suitable arrangement can be employed for variation of the sizes or spacings of the vias 430. In one example, substantially identical vias 430 can be employed arranged with smaller spacings between them in area where higher emission intensity is desired, and with larger spacings between them in areas where lower emission intensity is desired (e.g., as in FIG. 8B). In another embodiments, the vias 430 can be positioned according to a regular grid pattern, with vias having larger diameters positioned in regions where higher emission intensity is desired and vias having smaller diameters positioned in regions where lower emission intensity is desired (e.g., as in FIG. 8A; fractions refer to a fraction of maximum via area). Suitable combinations of varying sizes and spacings can be advantageously employed. Any suitable emission intensity distribution can be selected including any of those described above (e.g., sloped, 1D-peaked, or 2D-peaked; sloped shown in FIGS. 8A and 8B).

In some embodiments the contact 420 can include one or more metals or metal alloys, and the contact 420 and the insulating layer 440 can be arranged so as to act as a composite optical reflector for light emitted by the device 400. In some embodiments the device 400 includes an electrode layer 450 between the p-doped semiconductor layer 410 and the insulating layer 440; the electrode layer 450 is in direct contact with the p-doped semiconductor layer 410. The electrode layer 450 is substantially transparent for light emitted by the device 400, and the vias 430 connect the p-doped semiconductor layer 410 to the contact 420 by connecting the electrode layer 450 to the contact 420 (i.e., vias 430 arranged as e-vias in this example). Any suitable electrode material can be employed; in some embodiments the electrode material includes indium tin oxide (ITO) or indium zinc oxide (IZO).

In addition to the vias 430 connected to the contact 420, in some embodiments the contact 420 can include one or more edge contacts positioned about the periphery of the device 400 (not shown). In some embodiments, the contact 520 can include one or more edge contacts 520 positioned about the periphery of the device 400 (not shown) or can include one or more areal contacts 520 on the same side of the device 400 as the contact 420 (e.g., as in FIG. 7) or on the opposite side of the device 400 (not shown). Additional conductive or insulating layers that might be employed for establishing connections among the doped semiconductor layers 410/510, the contacts 420/520, or the drive circuit 600 are omitted from the drawings for clarity. In some embodiments, the device 400 can include a second array of multiple electrically conductive vias (not shown) arranged across the device 400. In such embodiments the vias of that second array can connect the contact 520 to the second doped semiconductor layer 510, and each such via provides a corresponding discrete, localized, circumscribed electrical connections between the n-doped semiconductor layer 510 and the contact 520. In some such embodiments, the sizes or spacings of the vias of the second array can vary across the device 400 in a manner similar to such variations of the vias 430 of the first array described above.

In one or more embodiments, the edge contact can be designed to optimize trade-offs between luminance, voltage frequency (V_{f}), and internal quantum efficiency (IQE). In one or more embodiments, the edge contact is segmented. In one or more embodiments, the luminance distributed is tailored to the application. As used herein, the term “segmented” refers to a layer that is divided into more than one repetitive section. A segmented edge contact is a contact that is divided into more than one edge contact section, each section separated by an electrically insulating material.

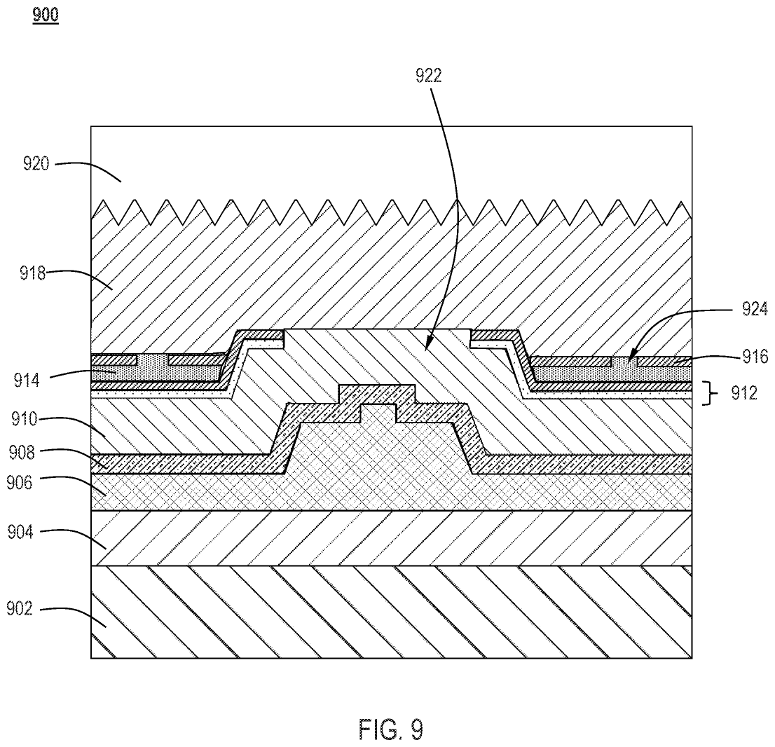

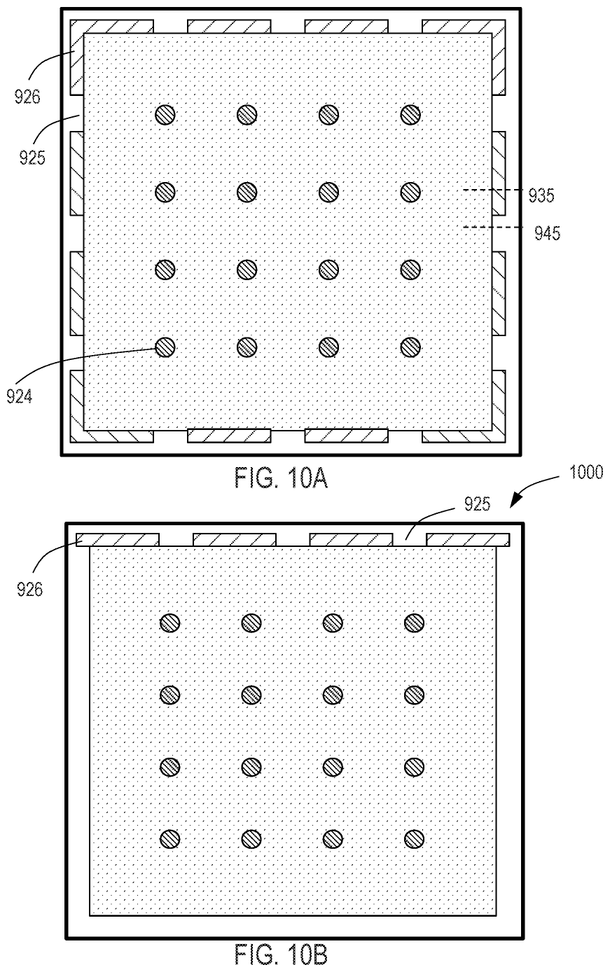

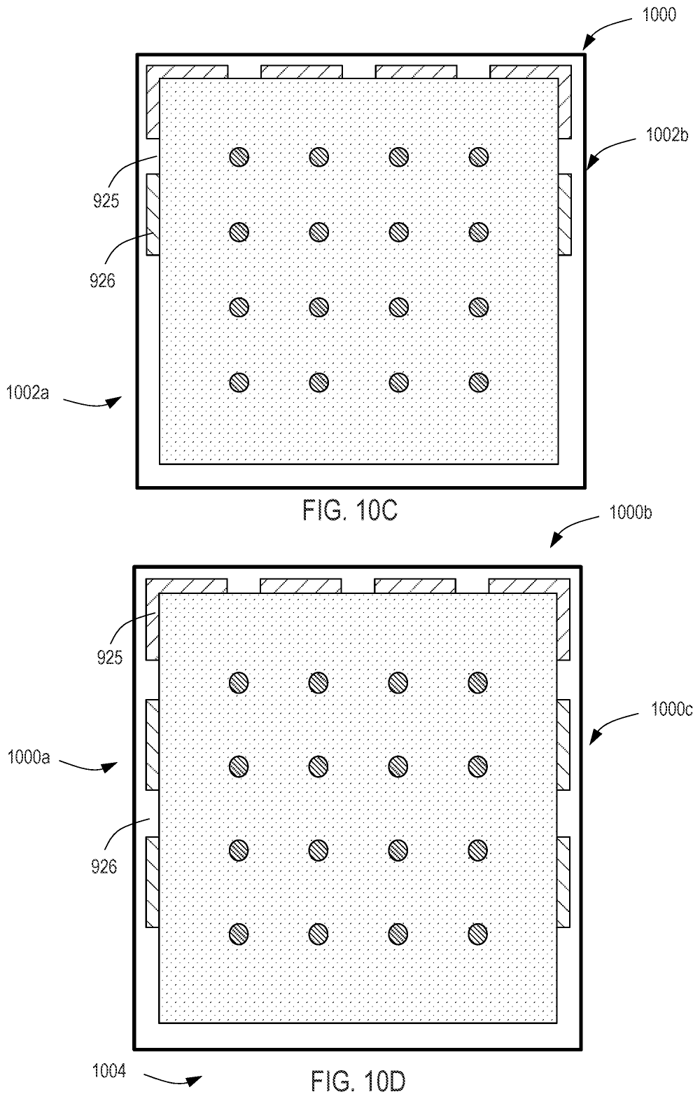

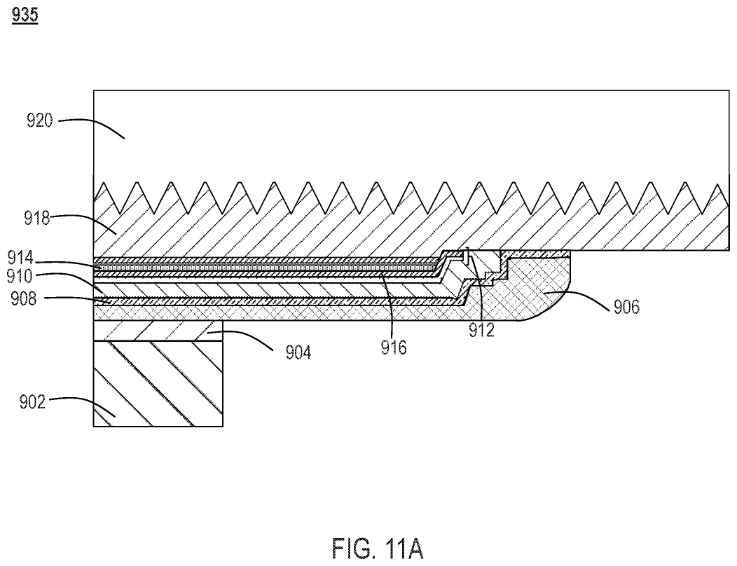

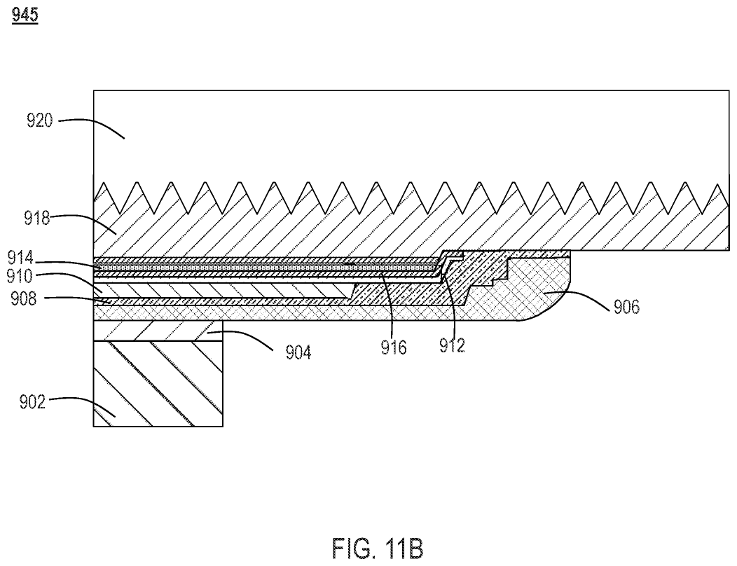

FIG. 9 is a cross-section view of a light-emitting diode (LED) device according to one or more embodiments. FIG. 9 is a N-via contact cross section. FIGS. 10A to 10D are composite contact die layouts with segmented edge n-contact arrangements for luminance steering according to one or more embodiments. FIG. 11A is a schematic cross-sectional view 935 of an edge contact 926 in FIG. 10A, and FIG. 11B is a schematic cross-sectional view 945 of contact 925 in FIG. 10A. The segmented edge n-contact drastically shifts peak luminance towards the center of the die with minimum V_{f} penalty.

Referring to FIGS. 9-11B, semiconductor layers 918 are on a substrate 920. The substrate may be any substrate known to one of skill in the art. In one or more embodiments, the substrate comprises one or more of sapphire, silicon carbide, silicon (Si), quartz, magnesium oxide (MgO), zinc oxide (ZnO), spinel, and the like. In one or more embodiments, the substrate is not patterned prior to the growth of the epitaxial layer(s). Thus, in some embodiments, the substrate is not patterned and can be considered to be flat or substantially flat. In other embodiments, the substrate is patterned, e.g., patterned sapphire substrate (PSS). In one or more specific embodiments, the substrate 920 is a patterned sapphire substrate. In one or more embodiments, a substrate is absent from the structure, and the structure is a thin-film architecture.

In one or more embodiments semiconductor layers 918 are grown, e.g., epitaxially, on the patterned substrate 920.

In one or more embodiments, the semiconductor layers 918 comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers 918 comprises one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN), aluminum indium gallium phosphide (AlInGaP), and the like. In one or more specific embodiments, the semiconductor layers 918 comprises a p-type layer, an active region, and an n-type layer. In one or more embodiments, the semiconductor layers 918 comprise a III-nitride material, and in specific embodiments epitaxial III-nitride material. In some embodiments, the III-nitride material comprises one or more of gallium (Ga), aluminum (Al), indium (In), and phosphorus (P). Thus, in some embodiments, the semiconductor layers 918 comprises one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. In one or more specific embodiments, the semiconductor layers 918 comprises a p-type layer, an active region, and an n-type layer.

In one or more embodiments, the substrate 920 is placed in a metalorganic vapor-phase epitaxy (MOVPE) reactor for epitaxy of LED device layers to grow the semiconductor layers 918.

In one or more embodiments, the semiconductor layers 918 comprise a stack of undoped III-nitride material and doped III-nitride material. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In specific embodiments, the semiconductor layers 918 comprise an n-type layer, an active region, and a p-type layer.

In one or more embodiments, the semiconductor layers 918 have a combined thickness in a range of from about 2 μm to about 10 μm, including a range of from about 2 μm to about 9 μm, 2 μm to about 8 μm, 2 μm to about 7 μm, 2 μm to about 6 μm, 2 μm to about 5 μm, 2 μm to about 4 μm, 2 μm to about 3 μm, 3 μm to about 10 μm, 3 μm to about 9 μm, 3 μm to about 8 μm, 3 μm to about 7 μm, 3 μm to about 6 μm, 3 μm to about 5 μm, 3 μm to about 4 μm, 4 μm to about 10 μm, 4 μm to about 9 μm, 4 μm to about 8 μm, 4 μm to about 7 μm, 4 μm to about 6 μm, 4 μm to about 5 μm, 5 μm to about 10 μm, 5 μm to about 9 μm, 5 μm to about 8 μm, 5 μm to about 7 μm, 5 μm to about 6 μm, 6 μm to about 10 μm, 6 μm to about 9 μm, 6 μm to about 8 μm, 6 μm to about 7 μm, 7 μm to about 10 μm, 7 μm to about 9 μm, or 7 μm to about 8 μm.

In one or more embodiments, an active region is formed between the n-type layer and the p-type layer of the semiconductor layer 918. The active region may comprise any appropriate materials known to one of skill in the art. In one or more embodiments, the active region is comprised of a III-nitride material multiple quantum wells (MQW), and a III-nitride electron blocking layer.

In one or more embodiments, a dielectric layer 916 is deposited on the semiconductor layer 918.

As used herein, the term “dielectric” refers to an electrical insulator material that can be polarized by an applied electric field. The dielectric material may comprise any suitable material known to the skilled artisan. In one or more embodiments, the dielectric material comprises a low refractive index material. In some embodiments, the dielectric material comprises a material have a refractive index in a range of from about 1.2 to about 1. In one or more embodiments, the dielectric layer includes, but is not limited to, oxides, e.g., silicon oxide (SiO₂), aluminum oxide (Al₂O₃), nitrides, e.g., silicon nitride (Si₃N₄). In one or more embodiments, the dielectric layer comprises silicon nitride (Si₃N₄). In one or more embodiments, the dielectric layer 916 comprises silicon oxide (SiO₂). In some embodiments, the dielectric layer 916 composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 916 is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. A PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similarly, to a thermal ALD process, a purge step maybe conducted between the delivery of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, the dielectric layer 916 has a thickness in a range of from about 10 nm to about 5 μm, including from about 100 nm to about 4 μm, from about 50 nm to about 4 μm, from about 200 nm to about 3 μm.

Referring to FIGS. 9 and 10, in one or more embodiments, a p-contact layer 914 is formed on the dielectric layer 916. The P-contact layer 914 may comprise any suitable metal known to one of skill in the art. In one or more embodiments, the P-contact layer 914 comprises silver (Ag). In one or more embodiments, the ohmic p-contact layer 914 is an indium tin oxide (IT) film deposited on GaN as a blanket film. The silver (Ag) contacts the ITO, which contacts the p-type semiconductor and dictates where current is injected in the semiconductor on the p-side.

In one or more embodiments, a bilayer dielectric layer 912 is deposited on the p-contact layer 914. The bilayer dielectric 912 may comprise any suitable material(s) known to the skilled artisan. In one or more embodiments, the bilayer dielectric 912 includes, but is not limited to, oxides, e.g., silicon oxide (SiO₂), aluminum oxide (Al₂O₃), nitrides, e.g., silicon nitride (Si₃N₄). In one or more embodiments, the bilayer dielectric 912 comprises silicon nitride (Si₃N₄) and silicon oxide (SiO₂). The combined bilayer dielectric 912 may have any suitable thickness. In some embodiments, the thickness of the combined bilayer dielectric layer 912 is in a range of from 0.1 μm to 1.5 μm or in a range of from 0.4 μm to 1.2 μm.

As illustrated in FIGS. 9 and 10, the dielectric layer 916, the P-contact layer 914, and the bilayer dielectric layer 912 are patterned to form at least one opening 922 in the dielectric layer 916, the P-contact layer 914, and the bilayer dielectric layer 912, exposing a top surface of the semiconductor layers 918.

In one or more embodiments, the dielectric layer 916, the P-contact layer 914, and the bilayer dielectric layer 912 are patterned according to any appropriate patterning technique known to one of skill in the art. In one or more embodiments, the dielectric layer 916, the P-contact layer 914, and the bilayer dielectric layer 912 are patterned by etching. According to one or more embodiments, conventional masking, wet etching and/or dry etching processes can be used to etch the dielectric layer 916, the P-contact layer 914, and the bilayer dielectric layer 912.

In other embodiments, a pattern is transferred to the dielectric layer 916, the P-contact layer 914, and the bilayer dielectric layer 912 using nanoimprint lithography. In one or more embodiments, the device 900 is etched in a reactive ion etching (RIE) tool using conditions that etch the dielectric layer 916, the P-contact layer 914, and the bilayer dielectric layer 912 efficiently but etch the semiconductor layers 918 very slowly or not at all. In other words, the etching is selective to the dielectric layer 916, the P-contact layer 914, and the bilayer dielectric layer 912 over the p-type layer. In a patterning step, it is understood that masking techniques may be used to achieve a desired pattern.

The opening 922 has a width in a range of from 1 μm to 20 μm, or in a range of from 5 μm to 15 μm, or from 7 μm to 12 μm.

In one or more embodiments, an N-contact layer 910 is formed. The N-contact layer 910 may comprise any suitable material known to the skilled artisan. In one or more embodiments, the N-contact layer 910 comprises an n-contact material selected from one or more of silver (Ag), aluminum (Al), titanium (Ti), nickel (Ni), chromium (Cr), and gold (Au). The opening 922 exposes the N-contact layer 910 and may be referred to as an N-via.

In one or more embodiments, the N-contact layer 910 is on a dielectric layer 908. The dielectric layer 908 may comprise any suitable material known to the skilled artisan. In one or more embodiments, the dielectric layer 908 includes, but is not limited to, oxides, e.g., silicon oxide (SiO₂), aluminum oxide (Al₂O₃), nitrides, e.g., silicon nitride (Si₃N₄). In one or more embodiments, the dielectric layer 908 comprises silicon nitride (Si₃N₄). In one or more embodiments, the dielectric layer 908 has a thickness in a range of from 0.5 μm to 3 μm.

In one or more embodiments, the dielectric layer 908 is on bonding layers 906, 904, which are on an under-bump metallization (UBM) layer 902. With reference to FIGS. 9 and 10, under bump metallization (UBM) material forms an under-bump metallization (UBM) layer 902. As used herein, “under bump metallization (UBM)” refers to the metal layer which is required for connecting a die to a substrate with solder bumps for flip-chip packages. In one or more embodiments, the UBM layer 902 may be a patterned, thin-film stack of material that provides an electrical connection from the die to a solder bump, provides a barrier function to limit unwanted diffusion from the bump to the die, and provides a mechanical interconnection of the solder bump to the die through adhesion to the die passivation and attachment to a solder bump pad. The UBM layer 902 may comprise any suitable metal known to the skilled artisan. In one or more embodiments, the UBM layer 902 may comprise gold (Au), tin (Sn), nickel (Ni), copper (Cu), titanium (Ti), chromium (Cr), and the like. In one or more embodiments, the UBM layer 902 comprises a solder layer and a metal stack.

In one or more embodiments, under bump metallization (UBM) may be achieved by any technique known to one of skill in the art including, but not limited to, a dry vacuum sputter method combined with electroplating. In one or more embodiments, a dry vacuum sputter method combined with electroplating consists of multi-metal layers being sputtered. In other embodiments, the UBM may be formed by any physical vapor deposition (PVD) process, including, but not limited to, sputtering, thermal evaporation, and e-beam evaporation.

Referring to FIG. 9, in some embodiments, at least one opening 924 is formed in the dielectric layer 916 to expose the P-contact layer 914. The at least one opening 924 is an eVia to the P-contact 914. The opening 924 has a width in a range of from 1 nm to 20 μm, or in a range of from 10 nm to 20 μm, or in a range of from 1 μm to 20 μm, or in a range of from 1 nm to 10 μm, or in a range of from 10 nm to 5 μm, or in a range of from 1 nm to 1 μm, or in a range of from 1 nm to 5 μm.

FIG. 10A is a composite contact die layout with a 4-sided segmented edge n-contact arrangement for luminance steering. The region 926 at the edge represents the where the n-metal contacts the n-semiconductor. This is opposed to a lack of contact at the die edge or full contact at the die edge. The edge segmentation can be made by creating an opening in the first dielectric layer 908 (chemical etch or other technique) and depositing the bonding layer 904 metal over the opening, similar to the n-Via contacts. The segmentation can have a uniform spacing or non-uniform spacing depending on the application, similar to FIG. 8B nVia spacing (increasing from top to bottom). It can also have different widths similar to FIG. 8A along its extent by controlling the width or length of the dielectric opening. The segmentation also does not need to apply to all sides of the die. For example, some sides can have full edge contact, others have segmented edge contact, and others still no edge contact (or any combination).

FIG. 10B is a composite die layout with 1-side 1000 segmented with an edge n-contact. The region 926 at the edge represents the where the n-metal contacts the n-semiconductor. This is opposed to a lack of contact at the die edge or full contact at the die edge. The edge segmentation can be made by creating an opening in the first dielectric layer 908 (chemical etch or other technique) and depositing the bonding layer 904 metal over the opening, similar to the n-Via contacts. The segmentation can have a uniform spacing or non-uniform spacing depending on the application, similar to FIG. 10A. In one or more embodiments, the current density and light emission is shifted toward the top edge of the die. The segmented edge can be located on any side of the die. This is useful for automotive low-beam applications or others that require a sharp cutoff in the far-field light distribution due to glare prevention. A full edge contact may not be required to meet voltage specifications and reduced metal area improves optical efficiency.

FIG. 10C is a composite die layout with 1-side 1000 segmented and 2-sides 1002a/1002b partially segmented with an edge n-contact. The region 926 at the edge represents the where the n-metal contacts the n-semiconductor. This is opposed to a lack of contact at the die edge or full contact at the die edge. The edge segmentation can be made by creating an opening in the first dielectric layer 908 (chemical etch or other technique) and depositing the bonding layer 904 metal over the opening, similar to the n-Via contacts. The segmentation can have a uniform spacing or non-uniform spacing depending on the application, similar to FIGS. 10A-10B. In one or more embodiments, current density and light distribution follow the edge contact down the partially segmented sides of the die. The location of the fully segmented n-edge contact can vary. The extent of the segmented edge contact on the other sides can also vary along the die edge. A full edge contact may not be required to meet voltage specifications and the reduced metal area improves optical efficiency.

FIG. 10D is a composite die layout with 3-sides 1000a/1000b/1000c segmented and 1-side 1004 not segmented. In one or more embodiments, the segmentation extends further down both sides of the die. Again, full edge contact may not be required to meet voltage specs and can improve optical efficiency. The region 926 at the edge represents the where the n-metal contacts the n-semiconductor. This is opposed to a lack of contact at the die edge or full contact at the die edge. The edge segmentation can be made by creating an opening in the first dielectric layer 908 (chemical etch or other technique) and depositing the bonding layer 904 metal over the opening, similar to the n-Via contacts. The segmentation can have a uniform spacing or non-uniform spacing depending on the application, similar to FIGS. 10A-10C.FIG. 11A is a schematic cross-sectional view 935 of an edge contact 926 of FIG. 10. As illustrated in FIG. 11A, the N-contact layer 910 is segmented by creating an opening in the dielectric layer 908 (chemical etch or other technique) and depositing the bonding layer 904 metal over the opening, similar to the n-Via contacts. The segmented edge n-contact drastically shifts peak luminance towards the center of the die with minimum V_{f} penalty.

FIG. 11B is a schematic cross-sectional view 945 of a contact 925 in FIG. 10. As illustrated in FIG. 11B, the N-contact layer 910 is not segmented. The dielectric layer 908 extends from the semiconductor layers 918.

In one or more alternative embodiments, the edge contact can be designed to optimize trade-offs between luminance, voltage frequency (V_{f}), and internal quantum efficiency (IQE). In one or more embodiments, the edge contact is non-segmented. In one or more embodiments, the luminance distributed is tailored to the application. As used herein, the term “non-segmented” refers to a layer that is not divided into repetitive sections. A non-segmented edge contact is a contact that has a continuous edge contact along a side of a composite contact die layout. There is no separation by an electrically insulating material on the continuous edge contact.

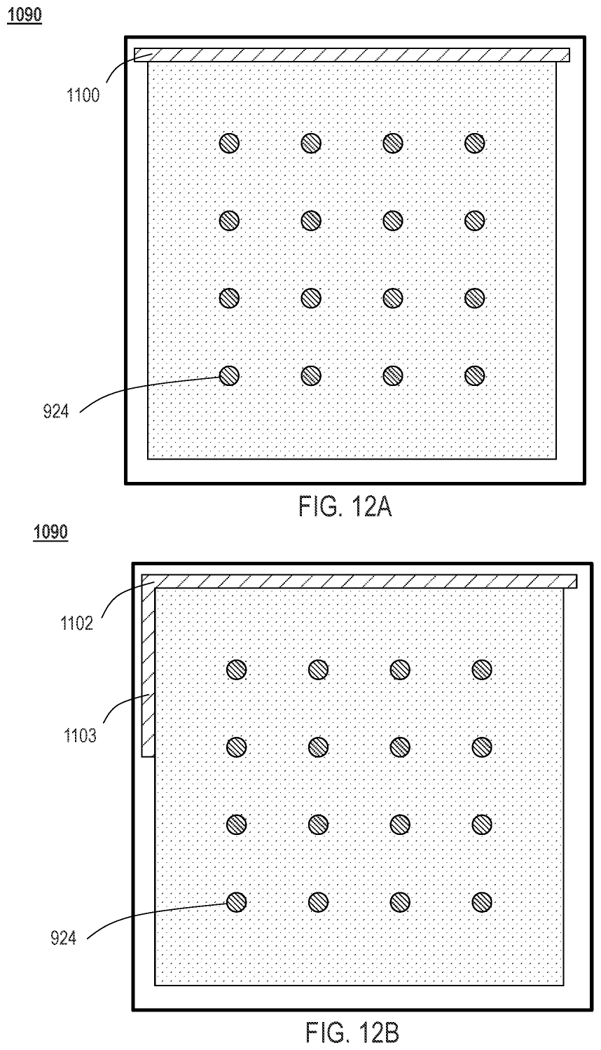

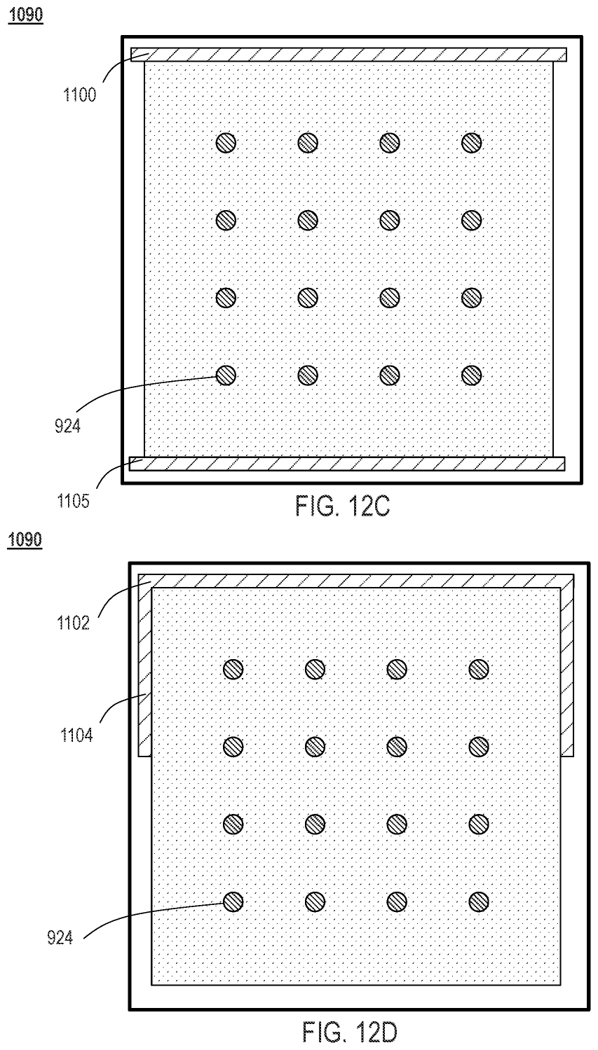

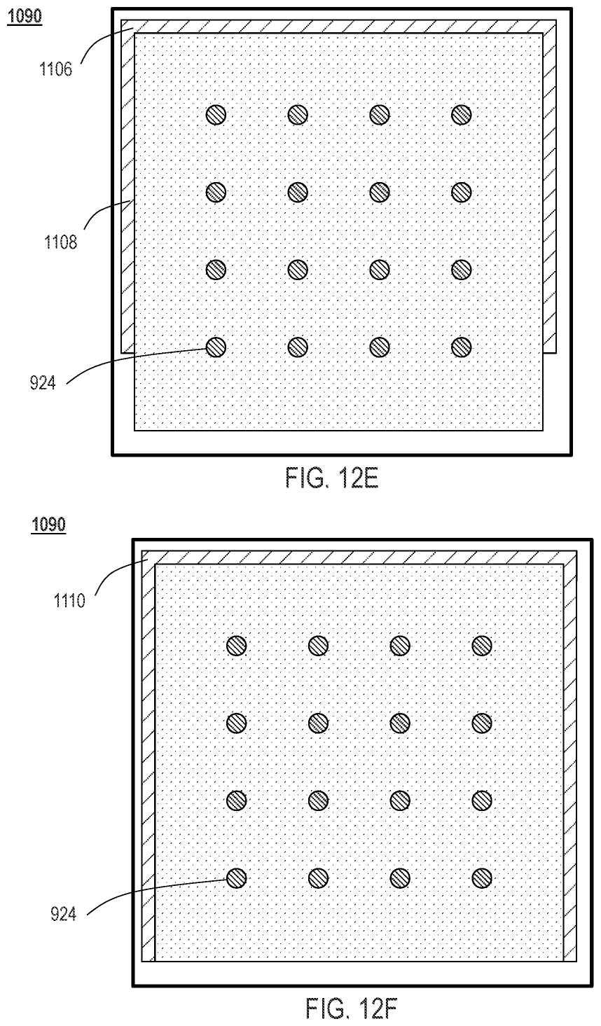

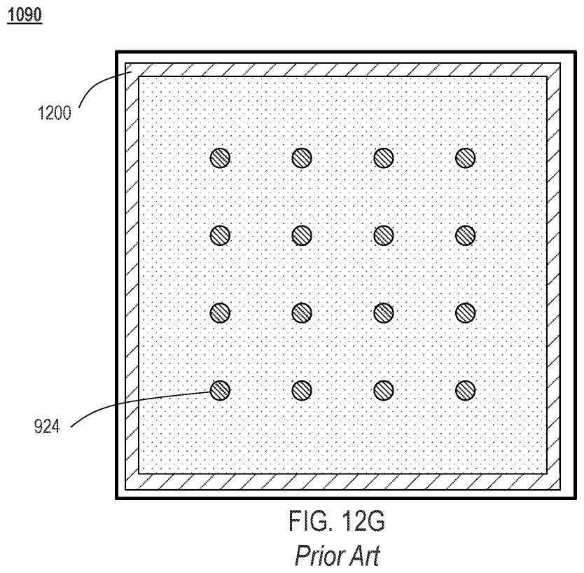

FIG. 12A is a composite contact die layout 1090 with a 1-sided non-segmented edge n-contact 1100. In one or more embodiments, three of the sides of the die layout 1090 do not contain an n-contact. The region 926 at the edge represents the where the n-metal contacts the n-semiconductor. In one or more embodiments, current density and light emission are shifted toward the top edge of the die. The non-segmented edge 1100 can be located on any side of the die. This is useful for automotive low-beam applications or others that require a sharp cutoff in the far-field light distribution due to glare prevention. A full edge contact may not be required to meet voltage specifications and reduced metal area improves optical efficiency.

FIG. 12B is a composite contact die layout 1090 having two sides with a non-segmented edge n-contact. In FIG. 12B, one top side has a non-segmented edge n-contact 1100, and a second adjacent side has at least a partial edge n-contact 1103 extending along an adjacent side of the die layout 1090. In one or more embodiments, two of the four sides of the die layout 1090 do not contain an n-contact. In one or more embodiments, the current density and light distribution follows the edge contact down the left side 1103 of the die layout 1090 without extending beyond half-way through. The non-segmented edge 1100 and the non-segmented edge 1103 can be located on any corner of the die layout 1090. In some embodiments, the non-segmented edge contact 1102 can extend partially down the second side of the die layout 1090, extending more than half-way through the second side. In other embodiments, the non-segmented edge contact 1103 can extend completely down the second side of the die layout 1090.

FIG. 12C is a composite die layout 1090 having two sides with a non-segmented edge n-contact. In FIG. 12C, one top side has a non-segmented edge n-contact 1100, and a second opposing side has a non-segmented edge n-contact 1105. In one or more embodiments, two sides of the four sides of the die layout 1090 do not contain an n-contact. In one or more embodiments, current density and light emission are shifted toward the opposite edges of the die layout 1090. The non-segmented edge 1100 and the second non-segmented edge 1105 can be located on any two opposing sides of the die.

FIG. 12D is a composite die layout having three sides with a non-segmented edge n-contact. In FIG. 12D, one side has a non-segmented edge-n contact 1102, and two sides adjacent to the first side non-segmented edge-n contact 1102 have a partial non-segmented 1104 edge n-contact. In one or more embodiments, the current density and light distribution follows the edge contact down left and right sides 1104 of the die without extending beyond half-way through. The location of the non-segmented 1102 n-edge contact can vary, same as in FIG. 12A. The extent of the segmented edge contact on the other side 1104 can also vary along the die edge. A full edge contact may not be required to meet voltage specifications and the reduced metal area improves optical efficiency.

FIG. 12E is a composite die layout with a 1-sided non-segmented edge n-contact 1106 and 2-sides and two sides 1108 having a partial non-segmented edge n-contact. As illustrated in FIG. 12D, the non-segmentation extends further down both sides 1108 of the die. Again, full edge contact may not be required to meet voltage specs and can improve optical efficiency.

FIG. 12G is a composite die layout with 3-sided 1110 non-segmented edge n-contact. In one or more embodiments, this layout has a full edge contact on three out of the four sides of the die layout 1090.

### EMBODIMENTS

Various embodiments are listed below. It will be understood that the embodiments listed below may be combined with all aspects and other embodiments in accordance with the scope of the invention.

Embodiment (a). A light emitting diode (LED) device comprising: a first doped semiconductor layer; a second doped semiconductor layer; a plurality of first contacts each electrically connected to the first doped semiconductor layer; a plurality of edge contacts each electrically connected to the second doped semiconductor layer, the plurality of edge contacts comprising a continuous non-segmented layer along at least one side of the second doped semiconductor layer with no separation by an insulating layer; and an array of a plurality of vias arranged across the device, the plurality of vias connecting the plurality of first contacts to the first doped semiconductor layer, each of the plurality of vias connecting at most one corresponding first contact of the plurality of first contacts to the first doped semiconductor layer.

Embodiment (b). The device of embodiment (a), wherein the plurality of edge contacts are along only one side of the second doped semiconductor layer.

Embodiment (c). The device of embodiment (a) to embodiment (b), wherein the plurality of edge contacts are along one side and partially along two sides adjacent the one side of the second doped semiconductor layer.

Embodiment (d). The device of embodiment (a) to embodiment (c), wherein the plurality of edge contacts are along one side and completely along two sides adjacent the one side of the second doped semiconductor layer.

Embodiment (e). wherein the plurality of edge contacts are along one side and partially along a second side adjacent the one side of the second doped semiconductor layer.

Embodiment (f). The device of embodiment (a) to embodiment (e), wherein the first doped semiconductor layer is between the plurality of first contacts and the second doped semiconductor layer.

Embodiment (g). The device of embodiment (a) to embodiment (f), further comprising an insulating layer between the first doped semiconductor layer and the plurality of first contacts.

Embodiment (h). The device of embodiment (a) to embodiment (g), wherein the plurality of vias connected the plurality of first contacts to the first doped semiconductor layer through the insulating layer.

Embodiment (i). The device of embodiment (a) to embodiment (h), further comprising an electrode layer between the first doped semiconductor layer and the insulating layer and in contact with the first doped semiconductor layer, wherein the electrode layer is substantially transparent.

Embodiment (j). The device of embodiment (a) to embodiment (i), wherein the electrode layer is arranged as multiple discrete areal segments separated by electrically insulating material so that transverse electrical conduction between adjacent areal segments is substantially prevented, and each areal segment of the electrode layer is connected to at most one corresponding contact of the plurality of first contacts.

Embodiment (k). The device of embodiment (a) to embodiment (j), wherein the second doped semiconductor layer is between the plurality of first contacts and the first doped semiconductor layer.

Embodiment (l). The device of embodiment (a) to embodiment (k), further comprising an insulating layer between the second doped semiconductor layer and the plurality of first contacts.

Embodiment (m). The device of embodiment (a) to embodiment (l), wherein the plurality of vias connect the plurality of first contacts to the first doped semiconductor layer through the insulating layer and the second doped semiconductor layer, and the plurality of vias are electrically insulated from the second doped semiconductor layer.

Embodiment (n). The device of embodiment (a) to embodiment (m), further comprising an array of a second plurality of vias arranged across the device, the second plurality of vias connecting the plurality of edge contacts to the second doped semiconductor layer.

Embodiment (o). The device of embodiment (a) to embodiment (n), wherein each via of the second plurality of vias connects at most one corresponding contact of the plurality of edge contacts to the second doped semiconductor layer.

Embodiment (p). A light emitting diode (LED) device comprising: an n-doped semiconductor layer; a p-doped semiconductor layer; a plurality of first contacts each electrically connected to the p-doped semiconductor layer; a plurality of edge contacts each electrically connected to the second doped semiconductor layer, the plurality of edge contacts comprising a continuous non-segmented layer along at least one side of the second doped semiconductor layer with no separation by an insulating layer; and an array of a plurality of vias arranged across the device, the plurality of vias connecting the plurality of first contacts to the p-doped semiconductor layer, each of the plurality of vias connecting at most one corresponding first contact of the plurality of first contacts to the p-doped semiconductor layer.

Embodiment (q). The device of embodiment (p), wherein the plurality of edge contacts are along only one side of the second doped semiconductor layer, or wherein the plurality of edge contacts are along one side and partially along a second side adjacent the one side of the second doped semiconductor layer, or wherein the plurality of edge contacts are along one side and a second opposing side of the second doped semiconductor layer.

Embodiment (r). The device of embodiment (p) to embodiment (q), wherein the plurality of edge contacts are along one side and partially along two sides adjacent the one side of the second doped semiconductor layer.

Embodiment (s), The device of embodiment (p) to embodiment (r), wherein the plurality of edge contacts are along one side and completely along two sides adjacent the one side of the second doped semiconductor layer.

Embodiment (t). The device of embodiment (p) to embodiment (r), wherein the plurality of edge contacts are along one side and completely along two sides adjacent the one side of the second doped semiconductor layer.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all embodiments, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light emitting diode (LED) device comprising:
a first doped semiconductor layer;
a second doped semiconductor layer;
a plurality of first contacts each electrically connected to the first doped semiconductor layer;
a plurality of edge contacts each electrically connected to the second doped semiconductor layer, the plurality of edge contacts comprising a continuous non-segmented layer along at least one side of the second doped semiconductor layer with no separation by an insulating layer; and
an array of a plurality of vias arranged across the device, the plurality of vias connecting the plurality of first contacts to the first doped semiconductor layer, each of the plurality of vias connecting at most one corresponding first contact of the plurality of first contacts to the first doped semiconductor layer.

2. The device of claim 1, wherein the plurality of edge contacts are along only one side of the second doped semiconductor layer.

3. The device of claim 1, wherein the plurality of edge contacts are along one side and partially along two sides adjacent the one side of the second doped semiconductor layer.

4. The device of claim 3, wherein the plurality of edge contacts are along one side and completely along two sides adjacent the one side of the second doped semiconductor layer.

5. The device of claim 1, wherein the plurality of edge contacts are along one side and partially along a second side adjacent the one side of the second doped semiconductor layer.

6. The device of claim 1, wherein the plurality of edge contacts are along one side and a second opposing side of the second doped semiconductor layer.

7. The device of claim 1, wherein the first doped semiconductor layer is between the plurality of first contacts and the second doped semiconductor layer.

8. The device of claim 7, further comprising an insulating layer between the first doped semiconductor layer and the plurality of first contacts.

9. The device of claim 8, wherein the plurality of vias connected the plurality of first contacts to the first doped semiconductor layer through the insulating layer.

10. The device of claim 9, further comprising an electrode layer between the first doped semiconductor layer and the insulating layer and in contact with the first doped semiconductor layer, wherein the electrode layer is substantially transparent.

11. The device of claim 10, wherein the electrode layer is arranged as multiple discrete areal segments separated by electrically insulating material so that transverse electrical conduction between adjacent areal segments is substantially prevented, and each areal segment of the electrode layer is connected to at most one corresponding contact of the plurality of first contacts.

12. The device of claim 1, wherein the second doped semiconductor layer is between the plurality of first contacts and the first doped semiconductor layer.

13. The device of claim 12, further comprising an insulating layer between the second doped semiconductor layer and the plurality of first contacts.

14. The device of claim 13, wherein the plurality of vias connect the plurality of first contacts to the first doped semiconductor layer through the insulating layer and the second doped semiconductor layer, and the plurality of vias are electrically insulated from the second doped semiconductor layer.

15. The device of claim 1, further comprising an array of a second plurality of vias arranged across the device, the second plurality of vias connecting the plurality of edge contacts to the second doped semiconductor layer.

16. The device of claim 15, wherein each via of the second plurality of vias connects at most one corresponding contact of the plurality of edge contacts to the second doped semiconductor layer.

17. A light emitting diode (LED) device comprising:
a first doped semiconductor layer;
a second doped semiconductor layer;
a plurality of first contacts each electrically connected to the second doped semiconductor layer;
a plurality of edge contacts each electrically connected to the second doped semiconductor layer, the plurality of edge contacts comprising a continuous non-segmented layer along at least one side of the second doped semiconductor layer with no separation by an insulating layer; and
an array of a plurality of vias arranged across the device, the plurality of vias connecting the plurality of first contacts to the second semiconductor layer, each of the plurality of vias connecting at most one corresponding first contact of the plurality of first contacts to the second semiconductor layer.

18. The device of claim 17, wherein the plurality of edge contacts are along only one side of the second doped semiconductor layer, or wherein the plurality of edge contacts are along one side and partially along a second side adjacent the one side of the second doped semiconductor layer, or wherein the plurality of edge contacts are along one side and a second opposing side of the second doped semiconductor layer.

19. The device of claim 17, wherein the plurality of edge contacts are along one side and partially along two sides adjacent the one side of the second doped semiconductor layer.

20. The device of claim 19, wherein the plurality of edge contacts are along one side and completely along two sides adjacent the one side of the second doped semiconductor layer.
